(19) United States
(12) Patent Application Publication
(10) Pub. No.: US 2023/0261045 A1
(43) Pub. Date: Aug. 17, 2023

(54) Semiconductor Device Including Air Spacer and Method of Manufacture

(71) Applicant: Taiwan Semiconductor Manufacturing Co., Ltd., Hsinchu (TW)

(72) Inventors: Wen-Kai Lin, Yilan County (TW); Che-Hao Chang, Hsinchu (TW); Yung-Cheng Lu, Hsinchu (TW); Chi On Chui, Hsinchu (TW)

(21) Appl. No.: 17/739,259

(22) Filed: May 9, 2022

Related U.S. Application Data
(60) Provisional application No. 63/268,178, filed on Feb. 17, 2022.

(51) Int. Cl. H01L 29/06; H01L 21/8234; H01L 27/088; H01L 29/66; H01L 29/78

(52) U.S. Cl. CPC H01L 29/0649; H01L 21/823431; H01L 27/0886; H01L 29/66795; H01L 29/785

(57) ABSTRACT

Semiconductor devices including air gaps between source/drain regions and a semiconductor substrate and methods of forming the same are disclosed. In an embodiment, a semiconductor device includes a semiconductor substrate; a first channel region on the semiconductor substrate; a gate structure on the first channel region; a first source/drain region adjacent the gate structure and the first channel region; a first inner spacer layer between the first source/drain region and the semiconductor substrate in a first direction perpendicular to a major surface of the semiconductor substrate; and a first air gap between the first source/drain region and the first inner spacer layer in the first direction.

### CROSS-REFERENCE TO RELATED APPLICATIONS

This application claims the benefit of U.S. Provisional Application No. 63/268,178, filed on Feb. 17, 2022, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (FET) in a three-dimensional view, in accordance with some embodiments.

FIGS. 2, 3, 4, 5, 6A, 6B, 7A, 7B, 8A, 8B, 9A, 9B, 10A, 10B, 11A, 11B, 11C, 12A, 12B, 12C, 12D, 12E, 12F, 13A, 13B, 13C, 13D, 13E, 13F, 13G, 13H, 13I, 14A, 14B, 14C, 15A, 15B, 16A, 16B, 17A, 17B, 18A, 18B, 19A, 19B, 19C, 20A, 20B, 20C, 21A, 21B, 21C, 22A, 22B, and 22C are cross-sectional views of intermediate stages in the manufacturing of nanostructure FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods of forming sealed air gaps (e.g., gaseous spacers) adjacent source/drain regions in semiconductor devices and semiconductor devices formed by the same. The methods include depositing a multi-layer stack on a semiconductor substrate, the multi-layer stack including alternating layers of a first semiconductor material and a second semiconductor material; etching the multi-layer stack and the semiconductor substrate to form a plurality of nanostructures from the multi-layer stack and first recesses adjacent the nanostructures and extending into the semiconductor substrate; etching side surfaces of the nanostructures through to first recesses to form sidewall recesses adjacent the first recesses; depositing two or more inner spacer layers in the first recesses and filling the sidewall recesses, wherein the inner spacer layers extend along side surfaces of the nanostructures and along the semiconductor substrate; etching the inner spacer layers to form inner spacers adjacent the nanostructures and the semiconductor substrate; and forming source/drain regions adjacent the inner spacers and the nanostructures. The source/drain regions may be formed by epitaxial deposition processes, and may seal bottom air gaps disposed vertically between the source/drain regions and the spacers on the semiconductor substrate. In some embodiments, the source/drain regions may also seal side air gaps disposed horizontally between the source/drain regions and the spacers disposed on the nanostructures. The side air gaps may be disposed vertically between adjacent nanostructures formed of the same semiconductor material or vertically between a nanostructure and the semiconductor substrate. Providing the bottom air gaps and the side air gaps helps to reduce parasitic capacitance in devices including the air gaps, and helps to improve bottom isolation between the source/drain regions and the semiconductor substrate. This improves device performance, such as AC performance.

Embodiments are described below in a particular context, namely, a die comprising nanostructure FETs. Various embodiments may be applied, however, to dies comprising other types of transistors (e.g., fin field-effect transistors (FinFETs), planar transistors, or the like) in lieu of, or in combination with the nanostructure FETs.

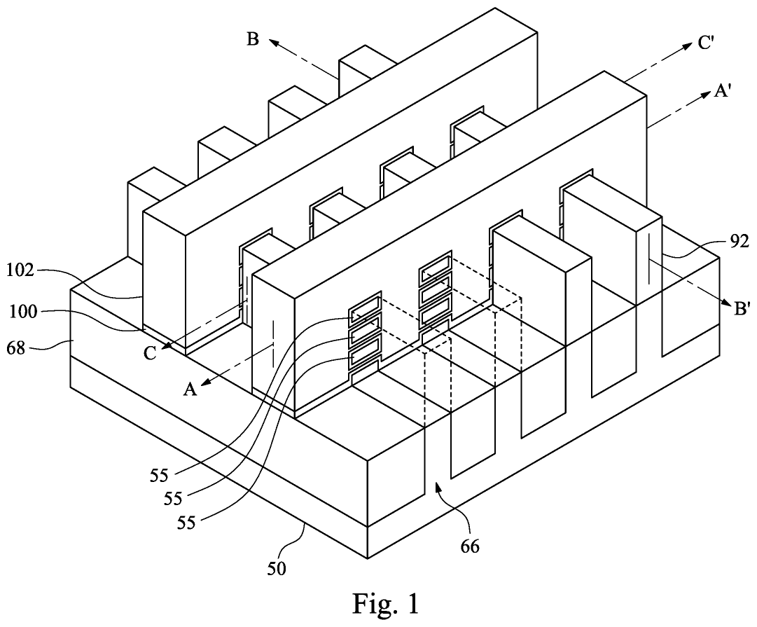

FIG. 1 illustrates an example of nanostructure FETs (e.g., nanowire FETs, nanosheet FETs (Nano-FETs), multi-bridge-channel FETs (MBCFETs), gate-all-around FETs (GAA FETs), nano-ribbon FETs, or the like) in a three-dimensional view, in accordance with some embodiments. The nanostructure FETs comprise nanostructures 55 (e.g., nanosheets, nanowires, nan-ribbons, or the like) over fins 66 on a substrate 50 (e.g., a semiconductor substrate). The nanostructures 55 act as channel regions for the nanostructure FETs. The nanostructures 55 may include materials suitable for forming channel regions in p-type transistors, n-type transistors, or the like. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring isolation regions 68.

Gate dielectric layers 104 are over top surfaces of the fins 66 and along top surfaces, sidewalls, and bottom surfaces of the nanostructures 55. Gate electrodes 106 are over the gate dielectric layers 104. Epitaxial source/drain regions 92 are disposed on the fins 66 on opposing sides of the gate dielectric layers 104 and the gate electrodes 106.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nanostructure FET. Cross-section B-B′ is perpendicular to cross-section A-A′ and is parallel to a longitudinal axis of a fin 66 of the nanostructure FET and in a direction of, for example, a current flow between the epitaxial source/drain regions 92 of the nanostructure FET. Cross-section C-C′ is parallel to cross-section A-A′ and extends through the epitaxial source/drain regions 9s of the nanostructure FET. Subsequent figures refer to these reference cross-sections for clarity.

Some embodiments discussed herein are discussed in the context of nanostructure FETs formed using a gate-last process. In other embodiments, a gate-first process may be used. Also, some embodiments contemplate aspects used in planar devices, such as planar FETs or in fin field-effect transistors (FinFETs).

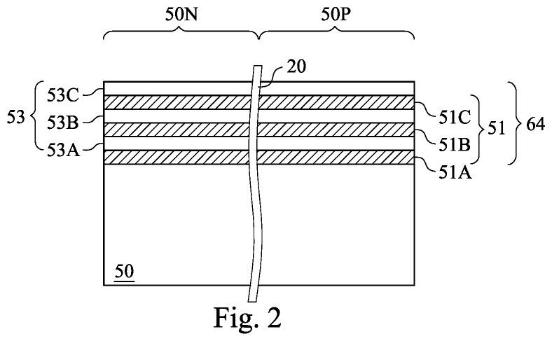

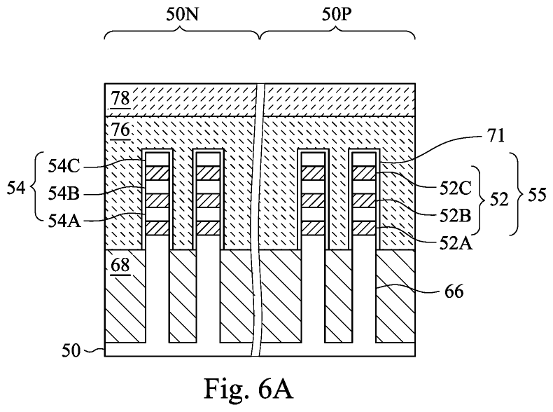

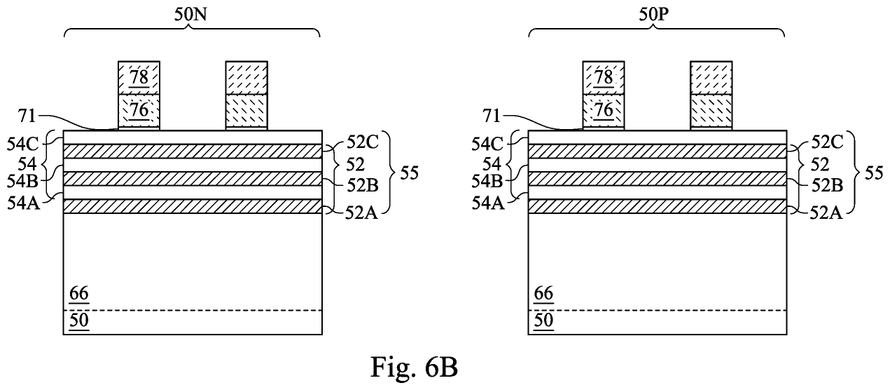

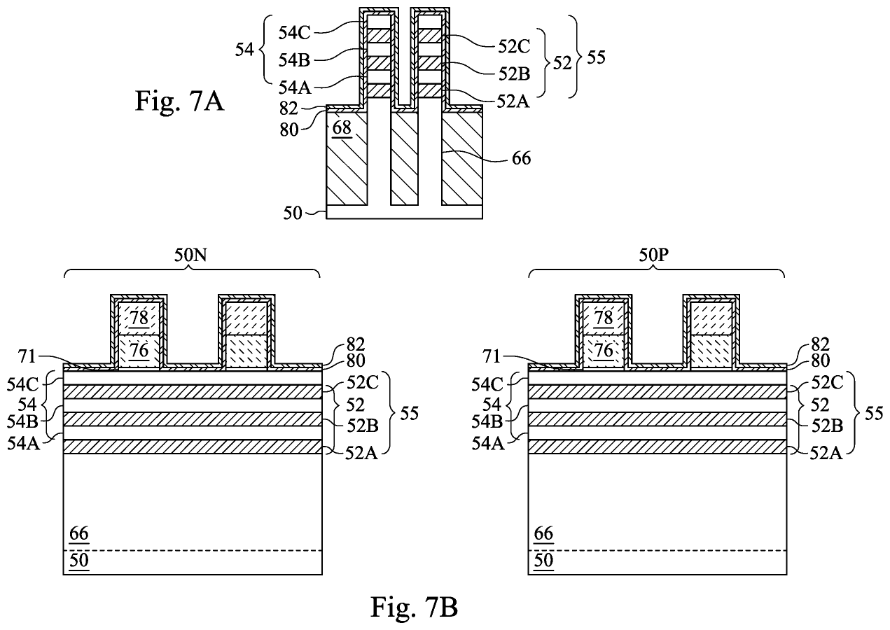

FIGS. 2 through 22C are cross-sectional views of intermediate stages in the manufacturing of nanostructure FETs, in accordance with some embodiments. FIGS. 2 through 5, 6A, 14A, 15A, 16A, 17A, 18A, 19A, 20A, 21A, and 22A illustrate reference cross-section A-A′ illustrated in FIG. 1. FIGS. 6B, 7B, 8B, 9B, 10B, 11B, 12B, 13B, 13D, 13E, 13F, 13G, 13H, 13I, 14B, 15B, 16B, 17B, 18B, 19B, 20B, 21B, and 22B illustrate reference cross-section B-B′ illustrated in FIG. 1. FIGS. 7A, 8A, 9A, 10A, 11A, 12A, 13A, 13C, 14C, 19C, 20C, 21C, and 22C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure FETs, and the p-type region 50P can be for forming p-type devices, such as PMOS transistors, e.g., p-type nanostructure FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nanostructure FETs in the p-type region 50P. The first semiconductor layers 51 will be removed and the second semiconductor layers 53 will be patterned to form channel regions of nanostructure FETs in the n-type region 50N. In some embodiments, the first semiconductor layers 51 may be removed and the second semiconductor layers 53 may be patterned to form channel regions of nanostructure FETs in the n-type region 50N, and the second semiconductor layers 53 may be removed and the first semiconductor layers 51 may be patterned to form channel regions of nanostructure FETs in the p-type region 50P.

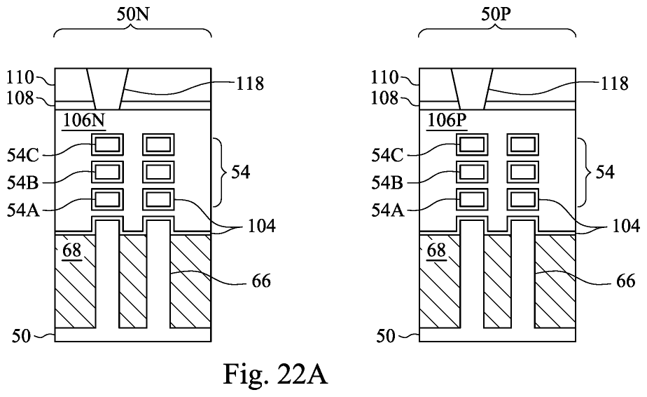

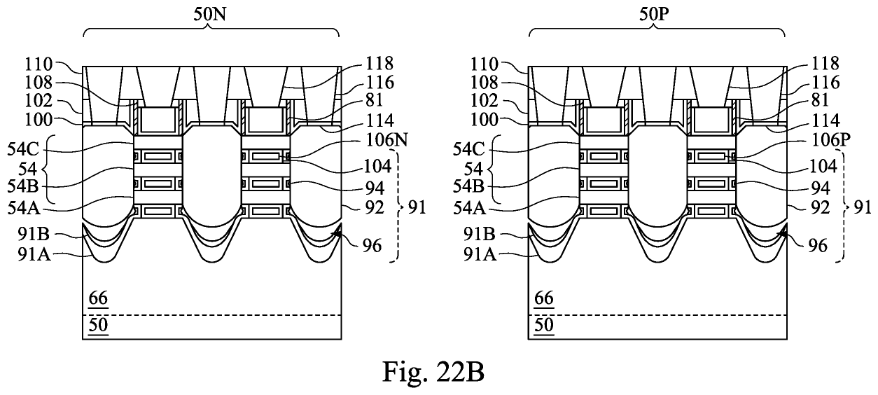

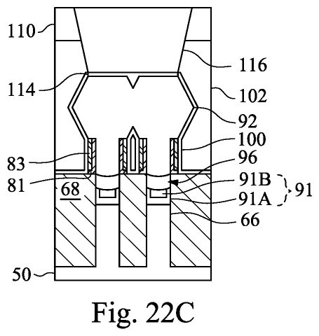

In some embodiments, the first semiconductor layers 51 may be removed and the second semiconductor layers 53 may be patterned to form channel regions of nanostructure FETS in both the n-type region 50N and the p-type region 50P. In some embodiments, the second semiconductor layers 53 may be removed and the first semiconductor layers 51 may be patterned to form channel regions of nanostructure FETs in both the n-type region 50N and the p-type region 50P. In such embodiments, the channel regions in both the n-type region 50N and the p-type region 50P may have a same material composition (e.g., silicon, or another semiconductor material) and may be formed simultaneously. FIGS. 22A, 22B, and 22C illustrate a structure resulting from embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In some embodiments, the first semiconductor layers 51 may be formed of a first semiconductor material suitable for p-type nanostructure FETs, such as silicon germanium, or the like, and the second semiconductor layers 53 may be formed of a second semiconductor material suitable for n-type nanostructure FETs, such as silicon, silicon carbon, or the like. The multi-layer stack 64 is illustrated as having a bottommost semiconductor layer suitable for p-type nanostructure FETs for illustrative purposes. In some embodiments, multi-layer stack 64 may be formed such that the bottommost layer is a semiconductor layer suitable for n-type nanostructure FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nanostructure FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nanostructure FETs.

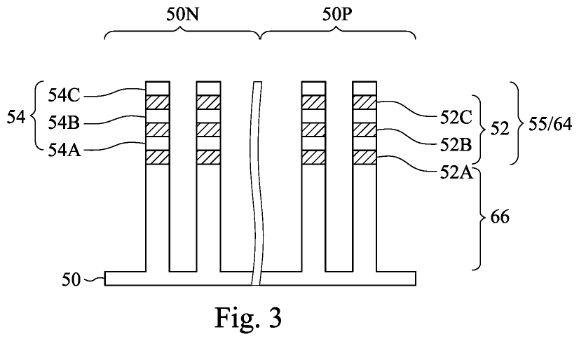

In FIG. 3, fins 66 are formed in the substrate 50 and nanostructures 55 are formed in the multi-layer stack 64. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in some embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

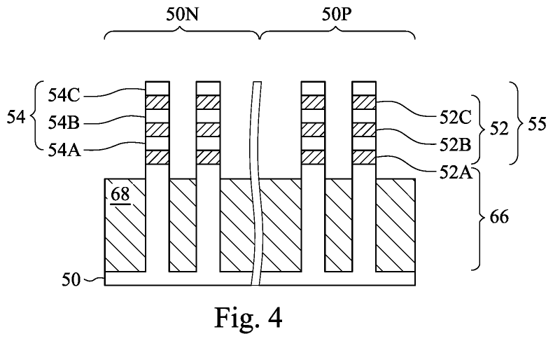

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent fins 66 and nanostructures 55. The insulation material may be an oxide, such as silicon oxide; a nitride, such as silicon nitride; the like; or a combination thereof, and may be formed by high-density plasma CVD (HDP-CVD), flowable CVD (FCVD), the like, or a combination thereof. Other insulation materials formed by any acceptable process may be used. In some embodiments, the insulation material is silicon oxide formed by an FCVD process. An anneal process may be performed once the insulation material is formed. In some embodiments, the insulation material is formed such that excess insulation material covers the nanostructures 55. Although the insulation material is illustrated as a single layer, some embodiments may utilize multiple layers. For example, in some embodiments, a liner (not separately illustrated) may be formed along surfaces of the substrate 50, the fins 66, and the nanostructures 55. A fill material, such as those discussed above, may be formed over the liner.

A removal process is applied to the insulation material to remove excess insulation material over the nanostructures 55. In some embodiments, a planarization process, such as a chemical mechanical polish (CMP), an etch-back process, combinations thereof, or the like, may be utilized. The planarization process exposes the nanostructures 55 such that top surfaces of the nanostructures 55 and the insulation material are level after the planarization process is complete.

The insulation material is recessed to form the STI regions 68. The insulation material is recessed such that the nanostructures 55 and upper portions of the fins 66 in the n-type region 50N and the p-type region 50P protrude from between neighboring STI regions 68. The top surfaces of the STI regions 68 may have flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer may be formed over a top surface of the substrate 50, and trenches may be etched through the dielectric layer to expose the underlying substrate 50. Epitaxial structures may be epitaxially grown in the trenches, and the dielectric layer may be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations. In situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66, the nanostructures 55, and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) are formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist is removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

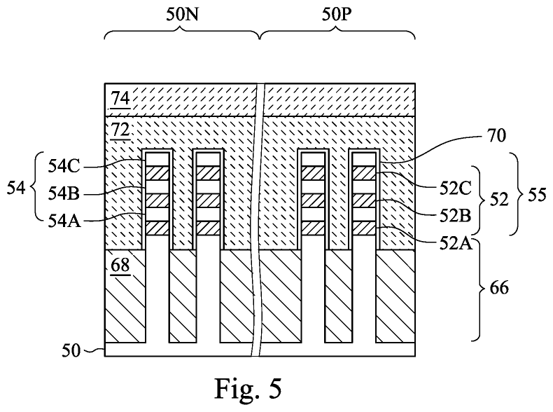

In FIG. 5, a dummy dielectric layer 70 is formed on the fins 66 and the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In the embodiment illustrated in FIG. 5, a single dummy gate layer 72 and a single mask layer 74 are formed across the n-type region 50N and the p-type region 50P. The dummy dielectric layer 70 is illustrated covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 21C illustrate various additional steps in the manufacturing of embodiment devices. FIGS. 7A, 8A, 9A, 10A, 11A, 12A, 13A, 13C, 14A, 14C, 15A, 16A, 19C, 20C, and 21C illustrate features in either the n-type region 50N or the p-type region 50P. In FIGS. 6A and 6B, the mask layer 74 (see FIG. 5) may be patterned using acceptable photolithography and etching techniques to form masks 78. The pattern of the masks 78 is transferred to the dummy gate layer 72 and to the dummy dielectric layer 70 to form dummy gates 76 and dummy gate dielectrics 71, respectively. The dummy gates 76 cover respective channel regions of the nanostructures 55. The pattern of the masks 78 may be used to physically separate each of the dummy gates 76 from adjacent dummy gates 76. The dummy gates 76 may also have a lengthwise direction substantially perpendicular to the lengthwise direction of respective fins 66 and nanostructures 55.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; surfaces and side surfaces of the nanostructures 55 and the masks 78; and side surfaces of the fins 66, the dummy gates 76, and the dummy gate dielectrics 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P. Appropriate type (e.g., p-type) impurities may be implanted into the exposed fins 66 and nanostructures 55 in the p-type region 50P. The mask may be removed. Subsequently, a mask, such as a photoresist, may be formed over the p-type region 50P, while exposing the n-type region 50N. Appropriate type impurities (e.g., n-type) may be implanted into the exposed fins 66 and nanostructures 55 in the n-type region 50N. The mask may be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

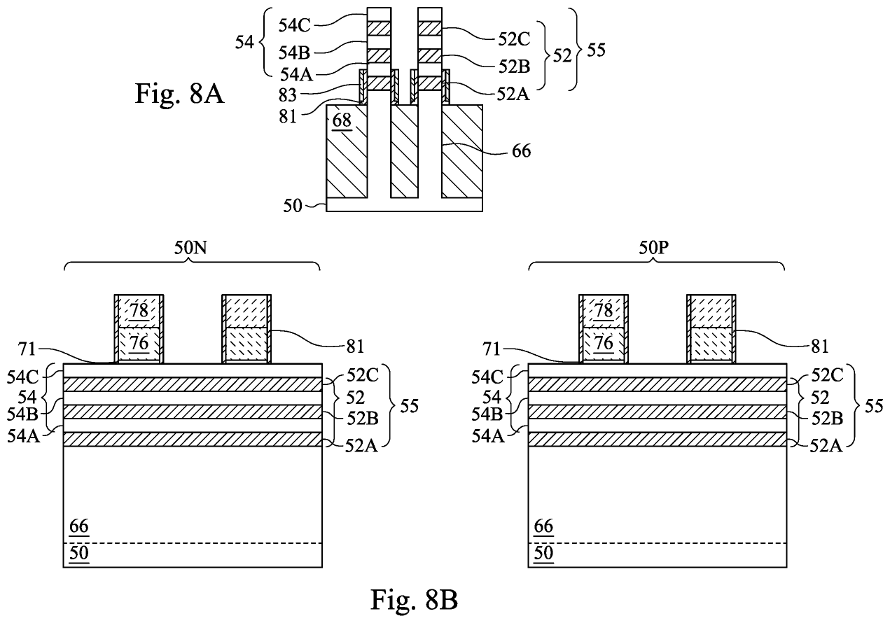

In FIGS. 8A and 8B, the first spacer layer 80 and the second spacer layer 82 are etched to form first spacers 81 and second spacers 83, respectively. As will be discussed in greater detail below, the first spacers 81 and the second spacers 83 act to self-align subsequently formed source/drain regions, control the growth of the subsequently formed source/drain regions, and protect sidewalls of the fins 66 and/or the nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate from the material of the first spacer layer 80, such that the first spacer layer 80 may act as an etch stop layer when patterning the second spacer layer 82. The second spacer layer 82 may act as a mask when patterning the first spacer layer 80. For example, the second spacer layer 82 may be etched using an anisotropic etch process wherein the first spacer layer 80 acts as an etch stop layer. Remaining portions of the second spacer layer 82 form second spacers 83, as illustrated in FIG. 8A. The second spacers 83 act as a mask while etching exposed portions of the first spacer layer 80, thereby forming first spacers 81, as illustrated in FIG. 8A.

As illustrated in FIG. 8A, the first spacers 81 and the second spacers 83 are disposed on sidewalls of the fins 66 and the nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In some embodiments, a portion of the second spacer layer 82 may remain over the first spacer layer 80 adjacent the masks 78, the dummy gates 76, and the dummy gate dielectrics 71 (e.g., the second spacers 83 may be formed over the first spacers 81 adjacent the masks 78, the dummy gates 76, and the dummy gate dielectrics 71).

It is noted that the above disclosure generally describes a process of forming spacers and LDD regions. Other processes and sequences may be used. For example, fewer or additional spacers may be utilized, different sequences of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

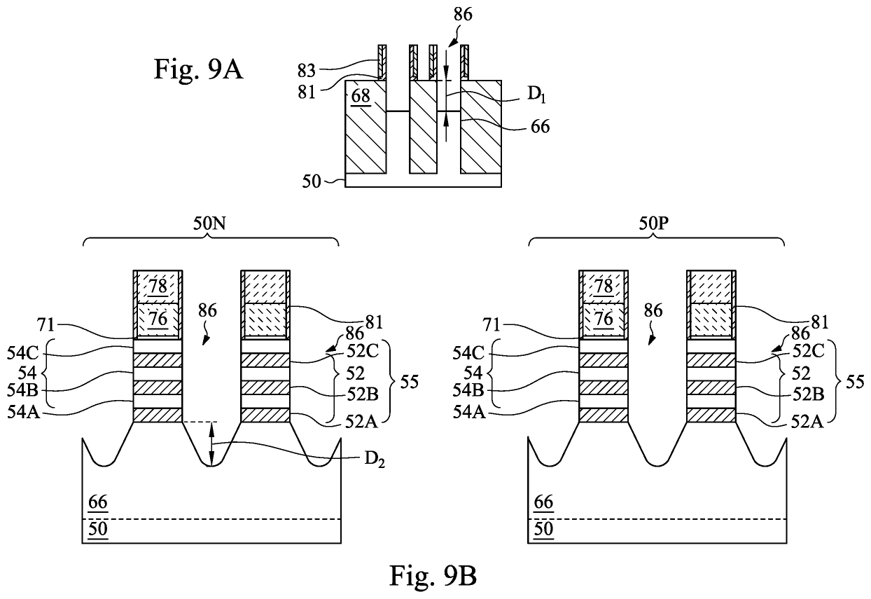

In FIGS. 9A and 9B, first recesses 86 are formed in the fins 66, the nanostructures 55, and the substrate 50. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 58 may be above bottom surfaces of the first recesses 86 (e.g., top surfaces of the fins 66). As illustrated in FIG. 9B, the first recesses 86 extend through the nanostructures 55 and into the substrate 50. Portions of the first recesses 86 extending into the substrate 50 may be V-shaped (as illustrated in FIG. 9B), U-shaped, or the like. In some embodiments, the fins 66 may be etched such that bottom surfaces of the first recesses 86 are disposed level with or above the top surfaces of the STI regions 68. The first recesses 86 may be formed by etching the fins 66, the nanostructures 55, and the substrate 50 using anisotropic etching processes, such as RIE, NBE, or the like. The first spacers 81, the second spacers 83, the masks 78, and the STI regions 68 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth. The first recesses 86 may have depths D₁ below top surfaces of the STI regions 68 in a range from about 30 nm to about 70 and depths D₂ below top surfaces of the fins 66 in a range from about 5 nm to about 40 nm. Forming the first recesses 86 to the depths D₁ and D₂ provides sufficient space such that air gaps may be sealed below subsequently formed source/drain regions, without extending so far into the substrate 50 that the substrate 50 is damaged.

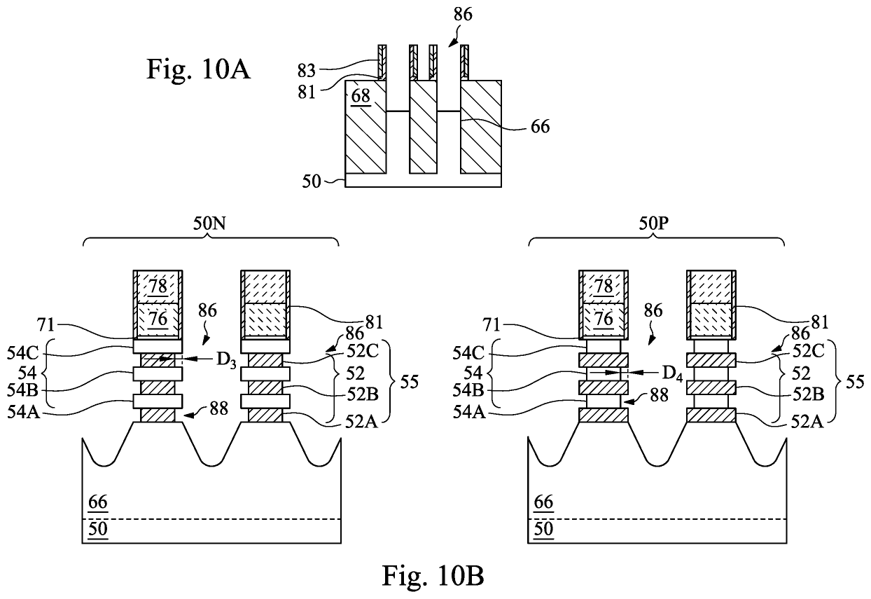

In FIGS. 10A and 10B, portions of sidewalls of the nanostructures 55 formed of the first semiconductor materials (e.g., the first nanostructures 52) exposed by the first recesses 86 are etched to form sidewall recesses 88 in the n-type region 50N, and portions of sidewalls of the nanostructures 55 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not separately illustrated) while etchants selective to the first semiconductor materials are used to etch the first nanostructures 52 such that the second nanostructures 54 and the substrate 50 remain relatively un-etched as compared to the first nanostructures 52 in the n-type region 50N. Similarly, the n-type region 50N may be protected using a mask (not separately illustrated) while etchants selective to the second semiconductor materials are used to etch the second nanostructures 54 such that the first nanostructures 52 and the substrate 50 remain relatively un-etched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

As illustrated in FIG. 10B, the sidewalls of the first nanostructures 52 may be recessed from the sidewalls of the second nanostructures 54 in the n-type region 50N a distance D₃ in a range from about 3 nm to about 15 nm. The sidewalls of the second nanostructures 54 may be recessed from the sidewalls of the first nanostructures 52 in the p-type region 50P a distance D₄ in a range from about 3 nm to about 15 nm. Recessing the first nanostructures 52 in the n-type region 50N and the second nanostructures 54 in the p-type region 50P by the prescribed distances provides sufficient isolation between subsequently formed source/drain regions and gate structures, without overly reducing the volume of the subsequently formed gate structures.

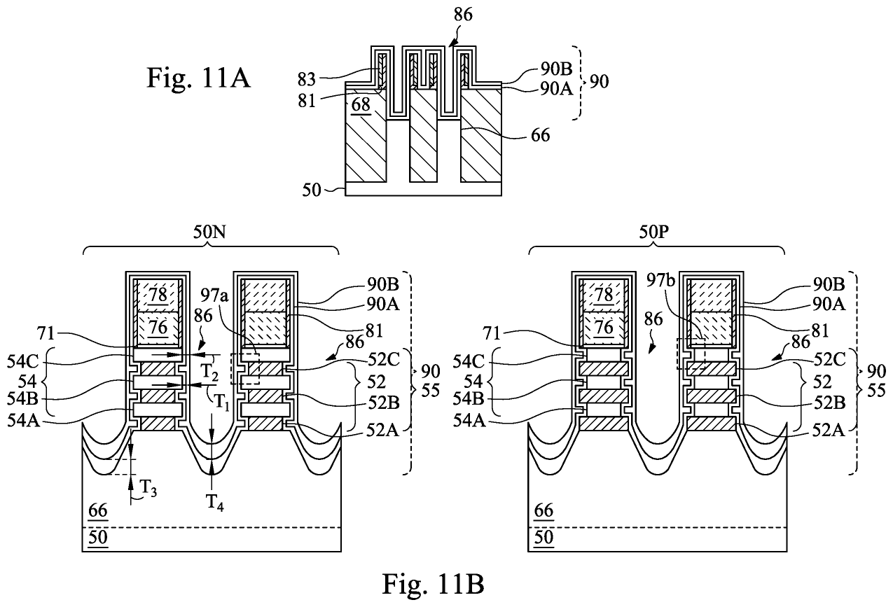

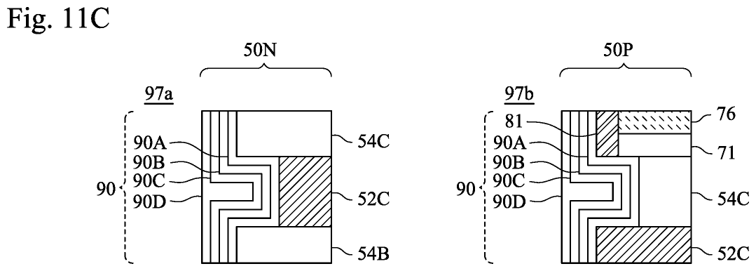

In FIGS. 11A through 11C, a multi-layer spacer film 90 is formed over the structures of FIGS. 10A and 10B. FIG. 11C illustrates detailed views of regions 97a and 97b of FIG. 11B. As illustrated in FIGS. 11B and 11C, the multi-layer spacer film 90 may fill the sidewall recesses 88 (illustrated in FIG. 10B). The multi-layer spacer film 90 is subsequently patterned to form inner spacers, which act as isolation features between subsequently formed source/drain regions and gate structures. As will be discussed in greater detail below, source/drain regions will be formed in the first recesses 86, while the first nanostructures 52 in the n-type region 50N and the second nanostructures 54 in the p-type region 50P will be replaced with corresponding gate structures.

FIGS. 11A and 11B illustrate an embodiment in which the multi-layer spacer film 90 includes a first inner spacer layer 90A and a second inner spacer layer 90B. FIG. 11C illustrates an embodiment in which the multi-layer spacer film 90 includes a first inner spacer layer 90A, a second inner spacer layer 90B, a third inner spacer layer 90C, and a fourth inner spacer layer 90D. The multi-layer spacer film 90 may include any number of inner spacer layers, and the number of inner spacer layers, thicknesses of the inner spacer layers, and materials selected for the inner spacer layers may be selected in order to control the shape and effective dielectric constant of subsequently formed inner spacers.

The inner spacer layers of the multi-layer spacer film 90 may be formed of dielectric materials, such as silicon carbon nitride (SiCN), silicon nitride (SiN), silicon carbon oxygen nitride (SiCON), silicon oxygen carbide (SiOC), silicon oxygen nitride (SiON), or the like. The inner spacer layers of the multi-layer spacer film 90 may be deposited by conformal deposition processes, such as ALD, CVD, or the like.

In the embodiment illustrated in FIGS. 11A and 11B, the first inner spacer layer 90A may be deposited to a thickness T₁ in a range from about 1 nm to about 15 nm, and the second inner spacer layer 90B may be deposited to a thickness T₂ in a range from about 3 nm to about 8 nm. A ratio of the thickness T₂ of the second inner spacer layer 90B to the thickness T₁ of the first inner spacer layer 90A may be in a range from about 0.5 to about 3. The first inner spacer layer 90A and the second inner spacer layer 90B fill the sidewall recesses 88. The first inner spacer layer 90A may be formed of a material having a relatively higher etch resistance and a relatively higher dielectric constant, and the second inner spacer layer 90B may be formed of a material having a relatively lower etch resistance and a relatively lower dielectric constant. The material of the second inner spacer layer 90B may also have a high etch selectivity relative to the material of the first inner spacer layer 90A. As such, the second inner spacer layer 90B may be removed without significantly removing the first inner spacer layer 90A. In some embodiments, a ratio of an etch rate of the material of the second inner spacer layer 90B to an etch rate of the material of the first inner spacer layer 90A (e.g., an etch selectivity of the second inner spacer layer 90B to the first inner spacer layer 90A) during a subsequent etch process may be greater than about 5. The material of the first inner spacer layer 90A may also have a high etch selectivity relative to the material of the second inner spacer layer 90B such that the first inner spacer layer 90A may be removed without significantly removing the second inner spacer layer 90B.

The first inner spacer layer 90A may have a dielectric constant in a range from about 4 to about 7, and the second inner spacer layer 90B may have a dielectric constant in a range from about 3 to about 6. In some embodiments, the etch selectivities and dielectric constants of the first inner spacer layer 90A and the second inner spacer layer 90B may be determined based on oxygen, carbon, and nitrogen concentrations of the first inner spacer layer 90A and the second inner spacer layer 90B. The first inner spacer layer 90A may be formed of a material having a higher carbon and/or nitrogen concentration, and the second inner spacer layer 90B may be formed of a material having a higher oxygen concentration. The first inner spacer layer 90A may have an oxygen concentration in a range from about 0 at. % to about 40 at. %, a nitrogen concentration in a range from about 5 at. % to about 50 at. %, and an oxygen concentration in a range from about 2 at. % to about 40 at. %. The second inner spacer layer 90B may have an oxygen concentration in a range from about 10 at. % to about 60 at. %, a nitrogen concentration in a range from about 10 at. % to about 60 at. %, and an oxygen concentration in a range from about 0 at. % to about 20 at. %.

Forming the first inner spacer layer 90A of the above-described materials and with the above-described thickness ensures that desired portions of the first inner spacer layer 90A are left intact after subsequent etching processes (such as etch processes used to remove the second inner spacer layer 90B, the first nanostructures 52 in the n-type region 50N, and the second nanostructures 54 in the p-type region 50P), which protects subsequently formed source/drain regions from damage. This improves device performance and reduces device defects. Forming the second inner spacer layer 90B of the above-described materials and with the above-described thickness reduces the effective dielectric constant of subsequently formed inner spacers including residual portions of the second inner spacer layer 90B and helps the second inner spacer layer 90B to be easily removed, which also helps reduce the effective dielectric constant of subsequently formed inner spacers. This improves device performance.

In some embodiments, the first inner spacer layer 90A and the second inner spacer layer 90B may have thicknesses in bottom portions of the first recesses 86 greater than thicknesses of the first inner spacer layer 90A and the second inner spacer layer 90B in the sidewall recesses 88, upper portions of the first recesses 86, and on surfaces of the first spacers 81, the second spacers 83, the STI regions 68, and the masks 78. For example, the first inner spacer layer 90A may have a T₃ thickness in the bottom portions of the first recesses 86 in a range from about 1 nm to about 10 nm, and the second inner spacer layer 90B may have a thickness T₄ in the bottom portions of the first recesses 86 in a range from about 5 nm to about 30 nm. A ratio of the thickness T₃ of the first inner spacer layer 90A in the bottom portions of the first recesses 86 to the thickness T₁ of the first inner spacer layer 90A along side surfaces of the nanostructures 55 may be in a range from about 0.2 to about 1. A ratio of the thickness T₄ of the second inner spacer layer 90B in the bottom portions of the first recesses 86 to the thickness T₂ of the second inner spacer layer 90B along side surfaces of the nanostructures 55 may be in a range from about 0.2 to about 1. Providing the first inner spacer layer 90A and the second inner spacer layer 90B with greater thicknesses in the bottom portions of the first recesses 86 ensures that portions of the substrate 50 and the fins 66 adjacent the first recesses 86 remain covered by the first inner spacer layer 90A and the second inner spacer layer 90B, even after etching the multi-layer spacer film 90 to form inner spacers. This prevents epitaxial growth of subsequently formed source/drain regions from the substrate 50 and the fins 66, such that air spacers are formed between the source/drain regions and the substrate 50 and the fins 66. The air spacers reduce capacitance and improve isolation in completed devices, improving device performance (such as AC performance) and reducing device defects.

In the embodiment illustrated in FIG. 11C, the multi-layer spacer film 90 includes four inner spacer layers (e.g., the first inner spacer layer 90A, the second inner spacer layer 90B, the third inner spacer layer 90C, and the fourth inner spacer layer 90D). The first inner spacer layer 90A may be deposited to a thickness in a range from about 0.5 nm to about 2 nm, and each of the second inner spacer layer 90B, the third inner spacer layer 90C, and the fourth inner spacer layer 90D may be deposited to a thickness in a range from about 0.5 nm to about 2 nm. The first inner spacer layer 90A, the second inner spacer layer 90B, the third inner spacer layer 90C, and the fourth inner spacer layer 90D fill the sidewall recesses 88.

The first inner spacer layer 90A may include materials previously described for the first inner spacer layer 90A, and each of the second inner spacer layer 90B, the third inner spacer layer 90C, and the fourth inner spacer layer 90D may include materials previously described for the second inner spacer layer 90B. In some embodiments, the first inner spacer layer 90A, the second inner spacer layer 90B, the third inner spacer layer 90C, and the fourth inner spacer layer 90D may have decreasing etch resistances and decreasing dielectric constants. Each of the first inner spacer layer 90A, the second inner spacer layer 90B, the third inner spacer layer 90C, and the fourth inner spacer layer 90D may be formed of materials having good etch selectivities to adjacent inner spacer layers, such that each layer of the multi-layer spacer film 90 may be selectively etched. Providing the multi-layer spacer film 90 with a greater number of inner spacer layers may be used to provide greater control over the shape and effective dielectric constant of subsequently formed inner spacers formed by patterning the multi-layer spacer film 90. In the embodiment of FIG. 11C in which the multi-layer spacer film 90 includes four inner spacer layers, the first inner spacer layer 90A may be formed with a smaller thickness than embodiments in which a smaller number of inner spacer layers are provided, which may be used to reduce the effective dielectric constant of subsequently formed inner spacers.

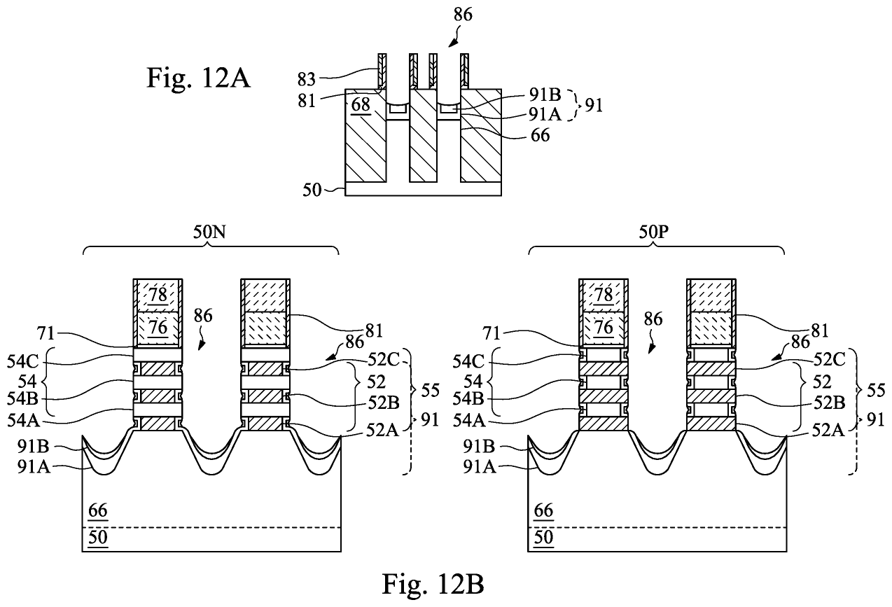

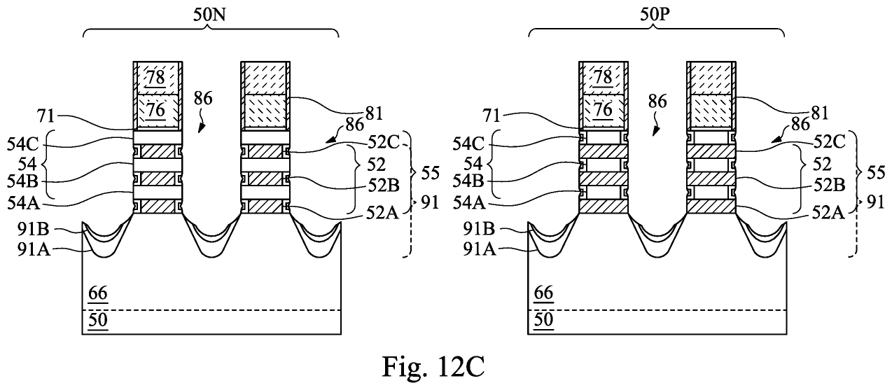

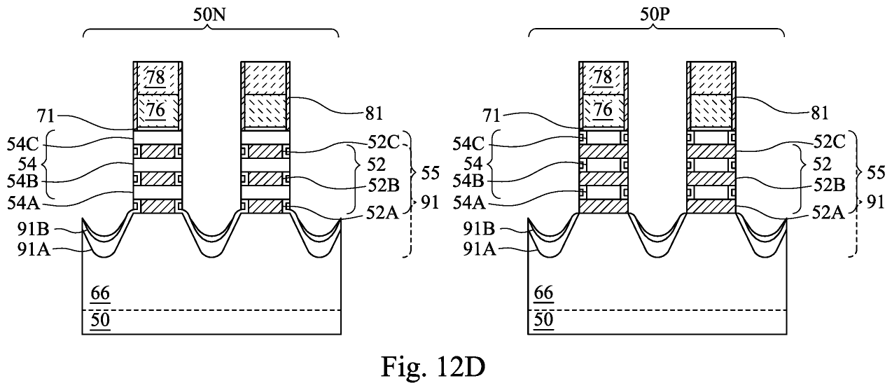

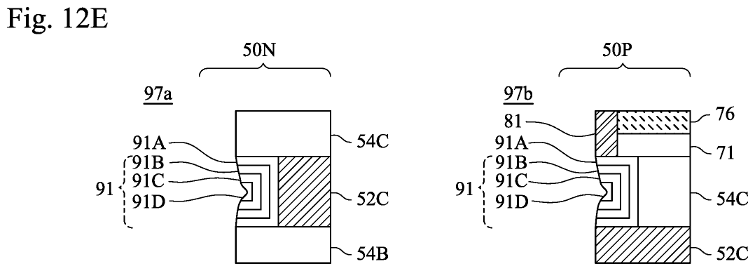

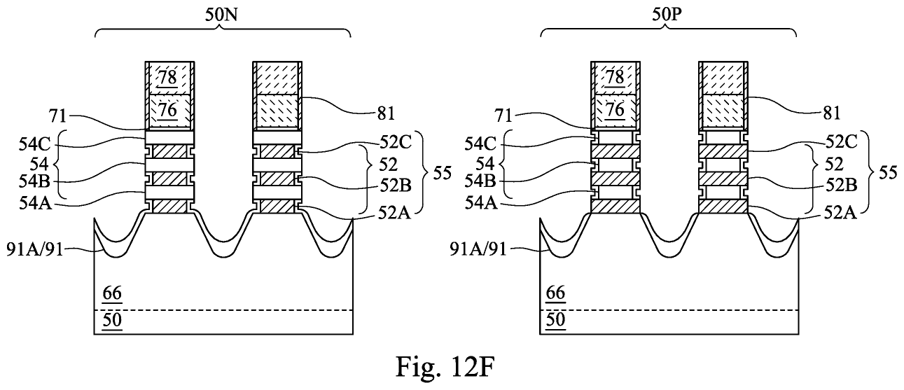

In FIGS. 12A through 12F, the multi-layer spacer film 90 is etched to form inner spacers 91. The processes used to etch the multi-layer spacer film 90 may be trimming processes, and may be referred to as inner-spacer trimming processes. FIG. 12E illustrates detailed views of regions 97a and 97b of FIG. 12B. In the various embodiments illustrated in FIGS. 12A through 12F, remaining portions of the first inner spacer layer 90A form first inner spacer portions 91A, remaining portions of the second inner spacer layer 90B form second inner spacer portions 91B, remaining portions of the third inner spacer layer 90C form third inner spacer portions 91C, and remaining portions of the fourth inner spacer layer 90D form fourth inner spacer portions 91D. The multi-layer spacer film 90 may be etched by one or more etching processes, such as dry etching processes, wet etching processes, combinations thereof, or the like. The etching processes used to etch the multi-layer spacer film 90 may be isotropic. In embodiments in which a wet etching process is used, the multi-layer spacer film 90 may be etched using sulfuric acid (H₂SO₄), phosphoric acid (H₃PO₄), dilute hydrofluoric acid (dHF), combinations thereof, or the like. In embodiments in which a dry etching process is used, the multi-layer spacer film 90 may be etched using a gas source comprising a mixture of trifluoromethane (CHF₃) and oxygen (O₂), a mixture of carbon tetrafluoride (CF₄) and oxygen, a mixture of nitrogen trifluoride (NF₃), fluoromethane (CH₃F), and trifluoromethane, combinations thereof, or the like; oxygen ashing or oxygen plasma; or the like.

As discussed previously, the etching processes used to etch the multi-layer spacer film 90 may etch the second inner spacer layer 90B, the third inner spacer layer 90C, and the fourth inner spacer layer 90D at faster rates than the first inner spacer layer 90A, such as at a rate of at least 5 times the rate at which the first inner spacer layer 90A is etched. As such, the second inner spacer layer 90B, the third inner spacer layer 90C, and the fourth inner spacer layer 90D may be etched, without significantly removing the material of the first inner spacer layer 90A. The first inner spacer layer 90A may then be etched by a selective etching process, without significantly removing material of the second inner spacer layer 90B, the third inner spacer layer 90C, and the fourth inner spacer layer 90D. This provides good control over the final shapes of the inner spacers 91.

In the embodiment illustrated in FIGS. 12A and 12B, the first inner spacer portions 91A remain in the sidewall recesses 88 (see FIGS. 10A and 10B) and in bottom portions of the first recesses 86. The first inner spacer portions 91A cover portions of the sidewall recesses 88 adjacent the nanostructures 55 and specifically cover portions of the sidewall recesses 88 adjacent the first nanostructures 52 in the n-type region 50N and portions of the sidewall recesses 88 adjacent the second nanostructures 54 in the p-type region 50P. The first inner spacer portions 91A extend continuously from the sidewall recesses 88 adjacent the first nanostructures 52A into the bottom portions of the first recesses 86 in the n-type region 50N. The first inner spacer portions 91A and the second inner spacer portions 91B may be at least partially recessed from side surfaces of the second nanostructures 54 in the n-type region 50N and side surfaces of the first nanostructures 52 in the p-type region 50P. The second inner spacer portions 91B remain in the sidewall recesses 88 and in the bottom portions of the first recesses 86. The first inner spacer portions 91A and the second inner spacer portions 91B are removed from side surfaces of the second nanostructures 54 in the n-type region 50N and side surfaces of the first nanostructures 52 in the p-type region 50P; side surfaces and top surfaces of the first spacers 81, the second spacers 83, and the STI regions 68; and top surfaces of the masks 78.

Providing the first inner spacer portions 91A in the sidewall recesses 88 prevents subsequent etching processes, such as etching processes used to remove the first nanostructures 52 from the n-type region 50N and etching processes used to remove the second nanostructures 54 from the p-type region 50P, from damaging source/drain regions subsequently formed in the first recesses 86. This reduces device defects and improves device performance. The second inner spacer portions 91B remaining in the sidewall recesses 88 have lower dielectric constants than the first inner spacer portions 91A, which reduces the effective dielectric constant of the inner spacers 91. Recessing the second inner spacer portions 91B and the first inner spacer portions 91A relative to sidewalls of the second nanostructures 54 in the n-type region 50N and the first nanostructures 52 in the p-type region 50P allows for air gaps to be sealed adjacent the inner spacers 91, which further reduces the effective dielectric constants of the inner spacers 91. This improves isolation between subsequently formed source/drain regions and subsequently formed gate structures, reduces capacitance, and improves device performance. Removing the first inner spacer portions 91A and the second inner spacer portions 91B from side surfaces of the first nanostructures 52 and the second nanostructures 54 allows for source/drain regions to be subsequently epitaxially grown from the first nanostructures 52 and the second nanostructures 54. The first inner spacer portions 91A and the second inner spacer portions 91B remaining in the bottom portions of the first recesses 86 cover the fins 66 and the substrate 50, which blocks epitaxial growth of the source/drain regions from the fins 66 and the substrate 50. This allows for air gaps to be sealed between the source/drain regions and the inner spacers 91 in the bottom portions of the first recesses 86. The air gaps and the second inner spacer portions 91B remaining in the bottom portions of the first recesses 86 provide improved isolation between the source/drain regions and the underlying fins 66 and substrate 50, provide reduced capacitance, and improve device performance.

In the embodiment illustrated in FIG. 12C, the multi-layer spacer film 90 is etched such that the first inner spacer portions 91A in the n-type region 50N are discontinuous between the sidewall recesses 88 adjacent the first nanostructures 52A and the bottom portions of the first recesses 86. Portions of the substrate 50 and the fins 66 may be exposed by the first inner spacer portions 91A and the second inner spacer portions 91B in both the n-type region 50N and the p-type region 50P. The first inner spacer portions 91A and the second inner spacer portions 91B remaining in the bottom portions of the first recesses 86 cover portions of the fins 66 and the substrate 50, which blocks epitaxial growth of the source/drain regions from the fins 66 and the substrate 50. This allows for air gaps to be sealed between the source/drain regions and the inner spacers 91 in the bottom portions of the first recesses 86. The air gaps and the second inner spacer portions 91B remaining in the bottom portions of the first recesses 86 provide improved isolation between the source/drain regions and the underlying fins 66 and substrate 50, provide reduced capacitance, and improve device performance. Exposing portions of the fins 66 and the substrate 50 allows larger source/drain regions to be formed, which provides improved device performance.

In the embodiment illustrated in FIG. 12D, side surfaces of the first inner spacer portions 91A and the second inner spacer portions 91B are aligned with side surfaces of the second nanostructures 54 in the n-type region 50N and the first nanostructures 52 in the p-type region 50P. The side profiles of the inner spacers 91 may be altered by adjusting the etching processes used to form the inner spacers 91 (such as performing the etching processes for a smaller amount of time). In embodiments in which the side surfaces of the first inner spacer portions 91A and the second inner spacer portions 91B are aligned with side surfaces of the second nanostructures 54 and the first nanostructures 52, the first inner spacer portions 91A and the second inner spacer portions 91B may contact subsequently formed source/drain regions without air gaps being formed horizontally between the inner spacers 91 and the source/drain regions.

In the embodiment illustrated in FIG. 12E, the inner spacers 91 are formed from four inner spacer layers (e.g., first inner spacer portions 91A are formed from the first inner spacer layer 90A (illustrated in FIG. 11C), second inner spacer portions 91B are formed from the second inner spacer layer 90B, third inner spacer portions 91C are formed from the third inner spacer layer 90C, and fourth inner spacer portions 91D are formed from the fourth inner spacer layer 90D). Forming the inner spacers 91 from a greater number of inner spacer layers allows for layers formed with greater etch resistances (such as the first inner spacer layer 90A) to be formed with smaller thicknesses, which may be used to reduce an effective dielectric constant of the inner spacers, reducing capacitance, and improving device performance. Providing a greater number of inner spacer layers provides more flexibility in the shape and effective dielectric constant of the inner spacers 91.

Side surfaces of the first inner spacer portions 91A, the second inner spacer portions 91B, the third inner spacer portions 91C, and the fourth inner spacer portions 91D may be at least partially recessed from side surfaces of the second nanostructures 54 in the n-type region 50N and side surfaces of the first nanostructures 52 in the p-type region 50P, or may be aligned with the side surfaces of the second nanostructures 54 and the first nanostructures 52, similar to the embodiment illustrated and discussed with respect to FIGS. 12A through 12D. The first inner spacer portions 91A, second inner spacer portions 91B, third inner spacer portions 91C, and fourth inner spacer portions 91D may be continuous or discontinuous between bottommost sidewall recesses 88 and the bottom portions of the first recesses 86, similar to the embodiments discussed above with respect to FIGS. 12A through 12C.

In the embodiment illustrated in FIG. 12F, the second inner spacer layer 90B is completely removed and the inner spacers 91 comprise the first inner spacer portions 91A. Removing the second inner spacer layer 90B leaves additional space for air gaps to be sealed in the sidewall recesses 88 horizontally between the inner spacers 91 and subsequently formed source/drain regions and in the bottom portions of the first recesses 86 vertically between the inner spacers 91 and the source/drain regions. The air gaps have lower dielectric constants than the second inner spacer layer 90B. As such, removing the second inner spacer layer 90B lowers the effective dielectric constant of the inner spacers 91, reduces capacitance, and improves device performance.

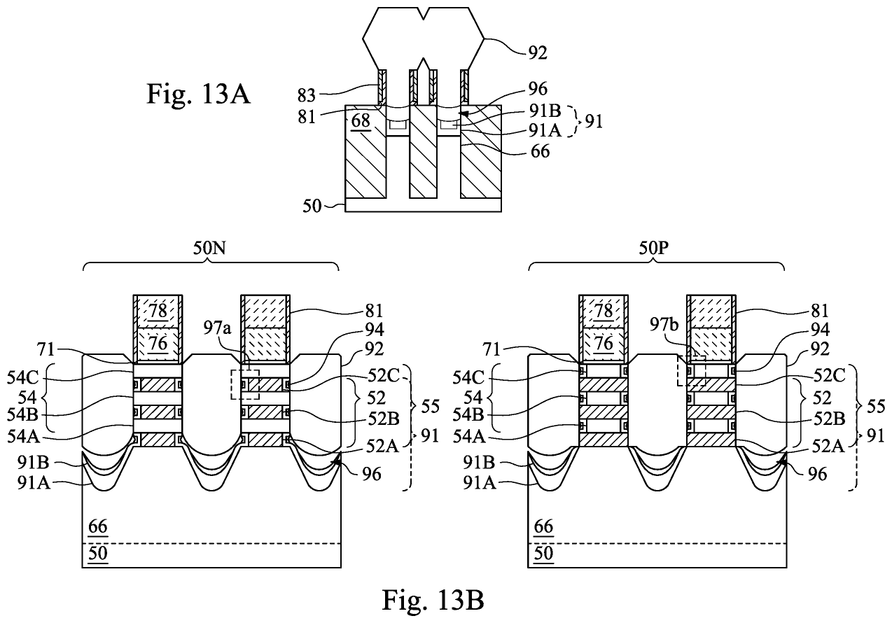

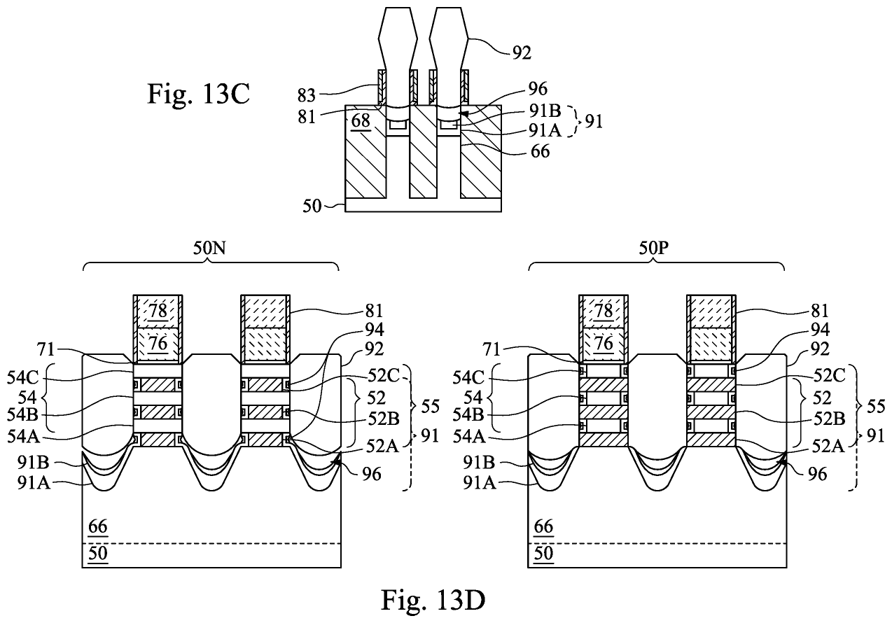

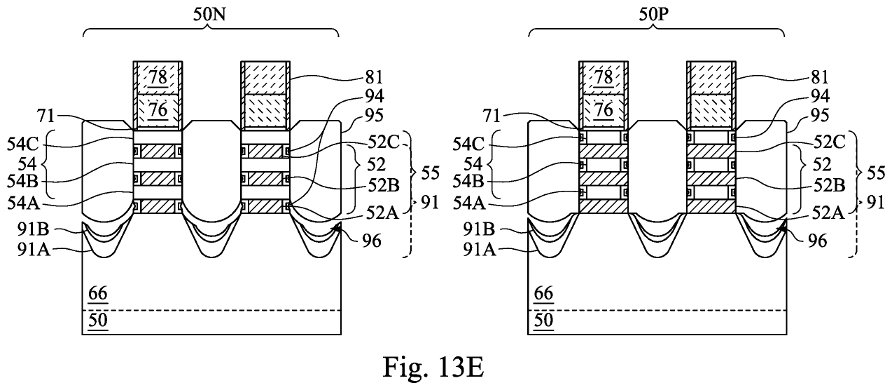

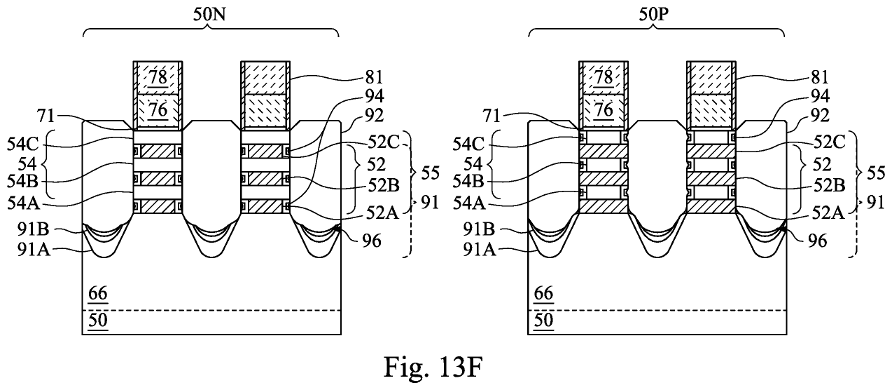

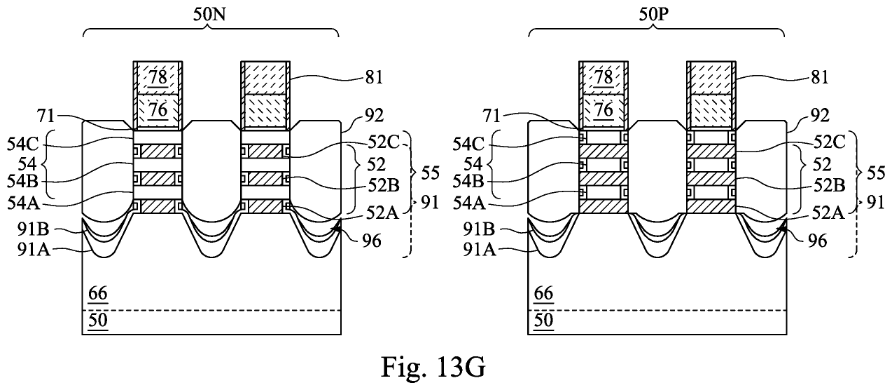

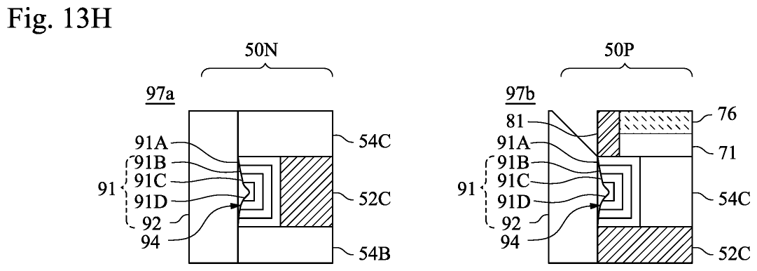

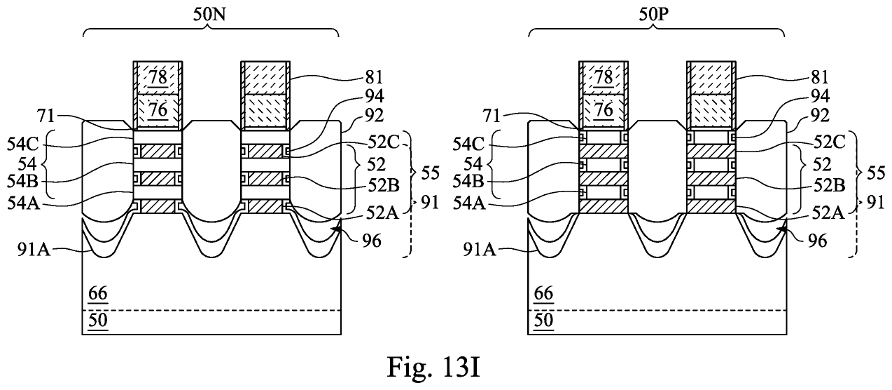

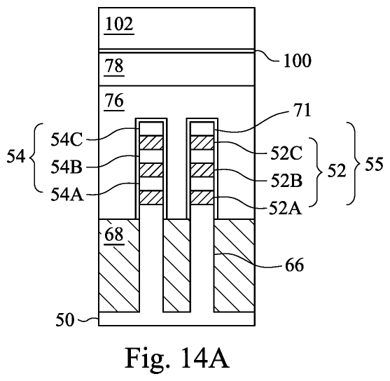

In FIGS. 13A through 13I, epitaxial source/drain regions 92 are formed in the first recesses 86. The epitaxial source/drain regions 92 seal side air gaps 94 (also referred to as side air spacers) in the sidewall recesses 88 (see FIG. 10B) horizontally between the epitaxial source/drain regions 92 and the inner spacers 91 adjacent the first nanostructures 52 in the n-type region 50N and the second nanostructures 54 in the p-type region 50P. The epitaxial source/drain regions 92 seal bottom air gaps 96 (also referred to as bottom air spacers) in the bottom portions of the first recesses 86 (see FIG. 10B) vertically between the epitaxial source/drain regions 92 and the inner spacers 91 on the substrate 50 and the fins 66. In some embodiments, the epitaxial source/drain regions 92 may exert stress on the second nanostructures 54 in the n-type region 50N and on the first nanostructures 52 in the p-type region 50P, thereby improving performance. As illustrated in FIG. 13B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the inner spacers 91 and the side air gaps 94 are used to separate the epitaxial source/drain regions 92 from the nanostructures 55 by an appropriate lateral distance so that the epitaxial source/drain regions 92 do not short out subsequently formed gates of the resulting nanostructure FETs. The inner spacers 91 and the bottom air gaps 96 are used to separate the epitaxial source/drain regions 92 from the substrate 50 and the fins 66 by an appropriate vertical distance so that leakage to the substrate 50 and the fins 66 is reduced, capacitance is reduced, and device performance is improved.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for forming source/drain regions in n-type nanostructure FETs. For example, if the second nanostructures 54 are silicon, the epitaxial source/drain regions 92 may include materials exerting a tensile strain on the second nanostructures 54, such as silicon, silicon carbide, phosphorous-doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for forming source/drain regions in p-type nanostructure FETs. For example, if the first nanostructures 52 are silicon germanium, the epitaxial source/drain regions 92 may comprise materials exerting a compressive strain on the first nanostructures 52, such as silicon-germanium, boron-doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nanostructure FET to merge as illustrated by FIG. 13A. In some embodiments, adjacent epitaxial source/drain regions 92 remain separated after the epitaxy process is completed as illustrated by FIG. 13C. In the embodiments illustrated in FIGS. 13A and 13C, the first spacers 81 may be formed to a top surface of the STI regions 68 thereby blocking the epitaxial growth. In some embodiments, the first spacers 81 may cover portions of the sidewalls of the nanostructures 55 further blocking the epitaxial growth. In some embodiments, the spacer etch used to form the first spacers 81 may be adjusted to remove the spacer material to allow the epitaxially grown region to extend to surfaces of the STI regions 68.

The epitaxial source/drain regions 92 may comprise one or more semiconductor material layers. For example, the epitaxial source/drain regions 92 may comprise a first semiconductor material layer, a second semiconductor material layer, and a third semiconductor material layer. Any number of semiconductor material layers may be used for the epitaxial source/drain regions 92. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the epitaxial source/drain regions 92 comprise three semiconductor material layers, the first semiconductor material layer may be deposited, the second semiconductor material layer may be deposited over the first semiconductor material layer, and the third semiconductor material layer may be deposited over the second semiconductor material layer.

The epitaxial source/drain regions 92 are epitaxially grown from the second nanostructure 54 in the n-type region 50N, the first nanostructures 52 in the p-type region 50P, and any exposed portions of the substrate 50 and the fins 66 in the n-type region 50N and the p-type region 50P. The inner spacers 91 in the sidewall recesses 88 prevent the epitaxial source/drain regions 92 from being epitaxially grown from the first nanostructures 52 in the n-type region 50N and the second nanostructures 54 in the p-type region 50P such that the side air gaps 94 are formed and sealed horizontally between the epitaxial source/drain regions 92 and the inner spacers 91 in the sidewall recesses 88. The side air gaps 94 are formed vertically between adjacent second nanostructures 54 and between the second nanostructure 54A and the substrate 50 and the fins 66 in the n-type region 50N and vertically between adjacent first nanostructures 52 in the p-type region 50P. The first inner spacer portions 91A in the sidewall recesses 88 protect the epitaxial source/drain regions 92 from subsequent etching processes, such as etching processes used to remove the first nanostructures 52 in the n-type region 50N and the second nanostructures 54 in the p-type region 50P. This reduces device defects and improves device performance. The inner spacers 91 in the bottom portions of the first recesses 86 prevent the epitaxial source/drain regions 92 from being epitaxially grown from the substrate 50 and the fins 66 in the bottom portions of the first recesses 86 such that the bottom air gaps 96 are formed and sealed vertically between the epitaxial source/drain regions 92 and the inner spacers 91 in the bottom portions of the first recesses 86. The dielectric constant of air is about 1, which is smaller than the dielectric constants of materials commonly used for inner spacers. As such, including the side air gaps 94 reduces an effective dielectric constant between the epitaxial source/drain regions 92 and subsequently formed gate structures, reduces capacitance, and improves device performance. Further, the inner spacers 91 and the bottom air gaps 96 have low dielectric constants and provide isolation between the epitaxial source/drain regions 92 and the substrate 50 and the fins 66, which reduces leakage to the substrate 50 and the fins 66, reduces capacitance, and improves device performance (such as AC performance).

FIGS. 13A through 13C illustrate the embodiment of FIGS. 12A and 12B, wherein the first inner spacer portions 91A, the second inner spacer portions 91B, and the side air gaps 94 are formed in the sidewall recesses 88; the first inner spacer portions 91A, the second inner spacer portions 91B, and the bottom air gaps 96 are formed in the bottom portions of the first recesses 86; and the first inner spacer portions 91A are continuous between the sidewall recesses 88 and the bottom portions of the first recesses 86 in the n-type region 50N. As illustrated in FIG. 13B, the epitaxial source/drain regions 92 may be separated from the first inner spacer portions 91A and the second inner spacer portions 91B in the bottom portions of the first recesses 86 such that the side air gaps 94 are continuous with the bottom air gaps 96. FIG. 13D illustrates the embodiment of FIGS. 12A and 12B, wherein the epitaxial source/drain regions 92 are formed to greater depths and contact the first inner spacer portions 91A in the bottom portions of the first recesses 86. The epitaxial source/drain regions 92 may be formed for a greater time than the embodiment illustrated in FIGS. 13A through 13C. Forming the epitaxial source/drain regions 92 in contact the first inner spacer portions 91A in the bottom portions of the first recesses 86 separates the side air gaps 94 from the bottom air gaps 96.

FIG. 13E illustrates the embodiment of FIG. 12C, wherein the first inner spacer portions 91A, the second inner spacer portions 91B, and the side air gaps 94 are formed in the sidewall recesses 88; the first inner spacer portions 91A, the second inner spacer portions 91B, and the bottom air gaps 96 are formed in the bottom portions of the first recesses 86; and the first inner spacer portions 91A are discontinuous between the sidewall recesses 88 and the bottom portions of the first recesses 86. As illustrated in FIG. 13E, the epitaxial source/drain regions 92 may be separated from the first inner spacer portions 91A and the second inner spacer portions 91B in the bottom portions of the first recesses 86 such that the side air gaps 94 are continuous with the bottom air gaps 96. FIG. 13F illustrates the embodiment of FIG. 12C, wherein the epitaxial source/drain regions 92 are formed to greater depths and contact the first inner spacer portions 91A and/or the second inner spacer portions 91B in the bottom portions of the first recesses 86. The epitaxial source/drain regions 92 may be formed for a greater time than the embodiment illustrated in FIG. 13E. Forming the epitaxial source/drain regions 92 in contact the first inner spacer portions 91A and/or the second inner spacer portions 91B in the bottom portions of the first recesses 86 separates the side air gaps 94 from the bottom air gaps 96.

FIG. 13G illustrates the embodiment of FIG. 12D, wherein the first inner spacer portions 91A and the second inner spacer portions 91B have side surfaces aligned with the nanostructures 55 and the first inner spacer portions 91A, the second inner spacer portions 91B, and the bottom air gaps 96 are formed in the bottom portions of the first recesses 86. As illustrated in FIG. 13G, the bottom air gaps 96 may extend adjacent to portions of the inner spacers 91 adjacent the first nanostructures 52A in the n-type region 50N. In some embodiments, the epitaxial source/drain regions 92 may be formed to greater depths such that the epitaxial source/drain regions 92 are in physical contact with the inner spacers 91 adjacent the first nanostructures 52A in the n-type region 50N. In the embodiment of FIG. 13G, the side air gaps 94 are omitted and only the bottom air gaps 96 are included.

FIG. 13H illustrates the embodiment of FIG. 12E, wherein the inner spacers 91 include the first inner spacer portions 91A, the second inner spacer portions 91B, the third inner spacer portions 91C, and the fourth inner spacer portions 91D. As illustrated in FIG. 13H, the first inner spacer portions 91A may be in physical contact with the epitaxial source/drain regions 92 and the second inner spacer portions 91B, the third inner spacer portions 91C, and the fourth inner spacer portions 91D may be separated from the epitaxial source/drain regions 92 by the side air gaps 94. However, in some embodiments, any of the first inner spacer portions 91A, the second inner spacer portions 91B, the third inner spacer portions 91C, and the fourth inner spacer portions 91D may physically contact or be separated from the epitaxial source/drain regions 92.

FIG. 13I illustrates the embodiment of FIG. 12F, wherein the second inner spacer layer 90B is removed; the first inner spacer portions 91A and the side air gaps 94 are formed in the sidewall recesses 88; the first inner spacer portions 91A and the bottom air gaps 96 are formed in the bottom portions of the first recesses 86; and the first inner spacer portions 91A are continuous between the sidewall recesses 88 and the bottom portions of the first recesses 86 in the n-type region 50N. As illustrated in FIG. 13I, the epitaxial source/drain regions 92 may be separated from the first inner spacer portions 91A and the second inner spacer portions 91B in the bottom portions of the first recesses 86 such that the side air gaps 94 are continuous with the bottom air gaps 96. In some embodiments, the epitaxial source/drain regions 92 are formed to greater depths and contact the first inner spacer portions 91A in the bottom portions of the first recesses 86. Forming the epitaxial source/drain regions 92 in contact the first inner spacer portions 91A in the bottom portions of the first recesses 86 separates the side air gaps 94 from the bottom air gaps 96. Removing the second inner spacer layer 90B enlarges the side air gaps 94 and the bottom air gaps 96, further reducing the effective dielectric constants, reducing capacitance, and improving device performance.

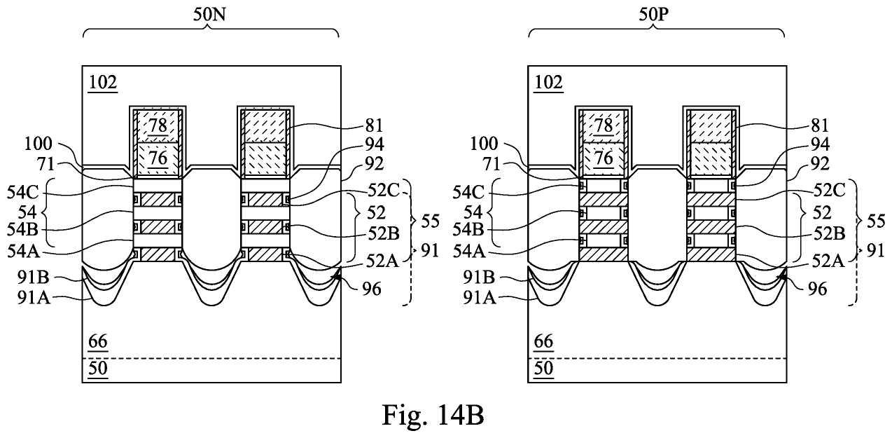

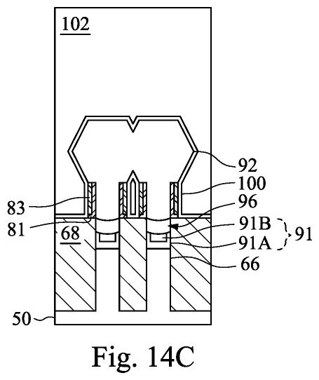

In FIGS. 14A through 14C, a first interlayer dielectric (ILD) 102 is deposited over the structure illustrated in FIGS. 6A, 13B, and 13A (the processes of FIGS. 7A through 13I do not alter the cross-section illustrated in FIGS. 6A), respectively. The first ILD 102 may be formed of a dielectric material, and may be deposited by any suitable method, such as CVD, plasma-enhanced CVD (PECVD), or FCVD. Dielectric materials may include phosphosilicate glass (PSG), borosilicate glass (BSG), boron-doped phosphosilicate glass (BPSG), un-doped silicate glass (USG), or the like. Other insulation materials formed by any acceptable process may be used. In some embodiments, a contact etch stop layer (CESL) 100 is disposed between the first ILD 102 and the epitaxial source/drain regions 92, the masks 78, and the first spacers 81. The CESL 100 may comprise a dielectric material, such as, silicon nitride, silicon oxide, silicon oxynitride, or the like, having a different etch rate than the material of the overlying first ILD 102.

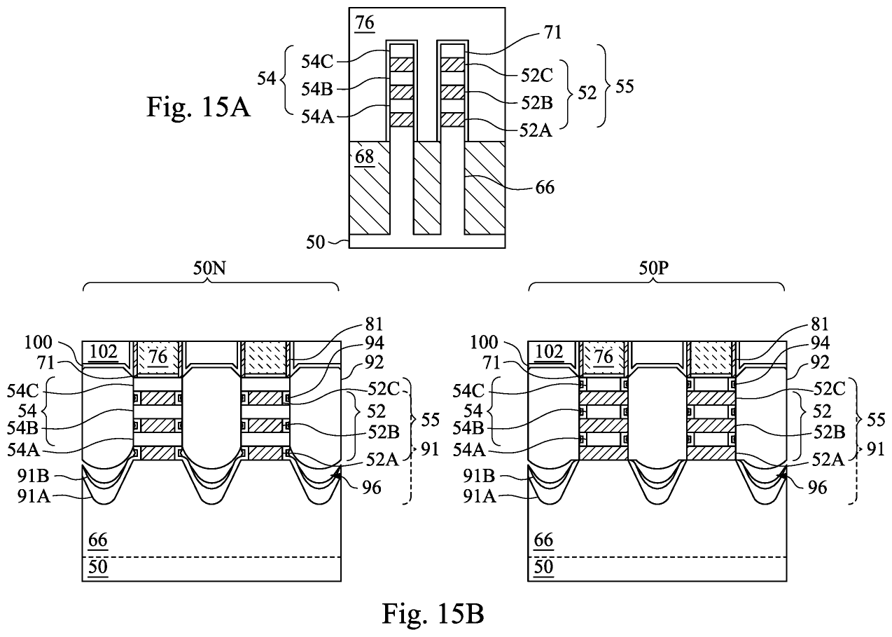

In FIGS. 15A and 15B, a planarization process, such as a CMP, may be performed to level top surfaces of the first ILD 102 and the CESL 100 with top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, the first ILD 102, and the CESL 100 are level with one another, within process variations. Accordingly, the top surfaces of the dummy gates 76 are exposed through the first ILD 102 and the CESL 100. In some embodiments, the masks 78 may remain, in which case the planarization process levels the top surfaces of the first ILD 102 and the CESL 100 with top surfaces of the masks 78 and the first spacers 81.

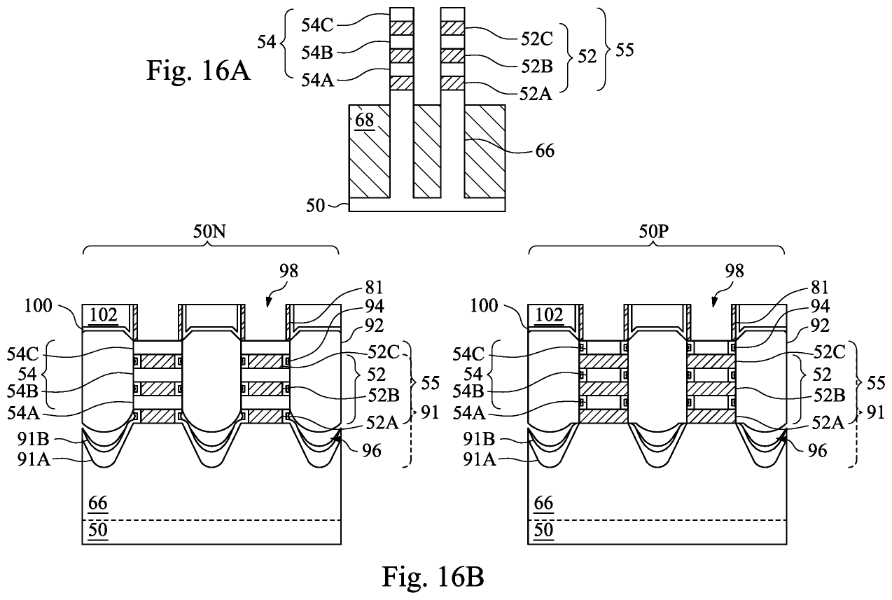

In FIGS. 16A and 16B, the dummy gates 76, and the masks 78 if present, are removed in one or more etching steps, so that recesses 98 are formed. Portions of the dummy gate dielectrics 71 in the recesses 98 are also be removed. In some embodiments, the dummy gates 76 and the dummy gate dielectrics 71 are removed by an anisotropic dry etching process. For example, the etching process may include a dry etching process using reaction gas(es) that selectively etch the dummy gates 76 at a faster rate than the first ILD 102, the CESL 100, or the first spacers 81. Each of the recesses 98 exposes and/or overlies portions of nanostructures 55, which act as channel regions in subsequently completed nanostructure FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

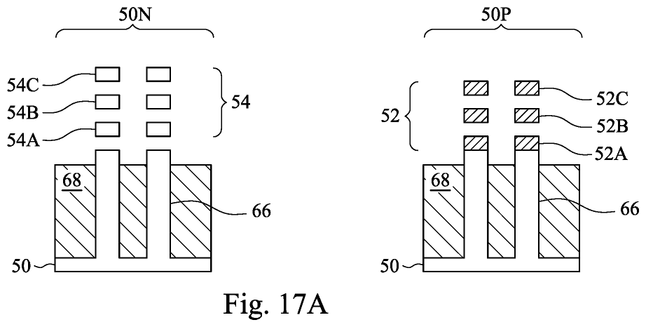

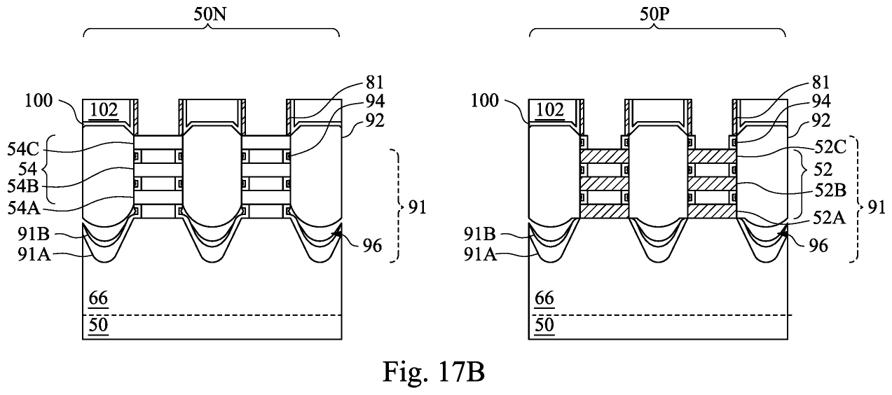

In FIGS. 17A and 17B, the first nanostructures 52 in the n-type region 50N and the second nanostructures 54 in the p-type region 50P are removed extending the recesses 98. The first nanostructures 52 may be removed by forming a mask (not separately illustrated) over the p-type region 50P and performing an isotropic etching process such as wet etching or the like using etchants which are selective to the materials of the first nanostructures 52, while the first inner spacer portions 91A, the second nanostructures 54, the substrate 50, the fins 66, the STI regions 68, the first ILD 102, the CESL 100, and the first spacers 81 remain relatively un-etched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not separately illustrated) over the n-type region 50N and performing an isotropic etching process such as wet etching or the like using etchants which are selective to the materials of the second nanostructures 54, while the first inner spacer portions 91A, the first nanostructures 52, the substrate 50, the fins 66, the STI regions 68, the first ILD 102, the CESL 100, and the first spacers 81 remain relatively un-etched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nanostructure FETs and p-type nanostructure FETs may have a same material composition, such as silicon, silicon germanium, or the like. FIGS. 22A through 22C illustrate a structure resulting from such embodiments where the channel regions in both the p-type region 50P and the n-type region 50N are provided by the second nanostructures 54 and comprise silicon, for example.

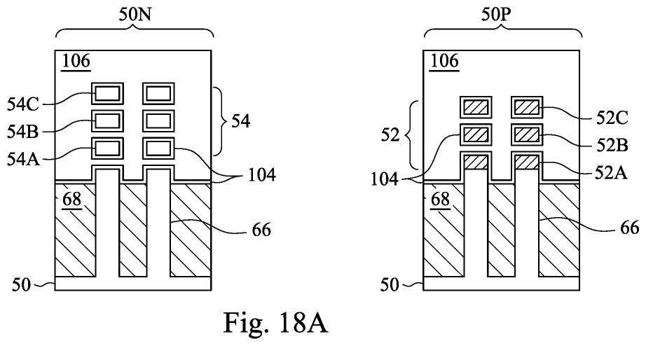

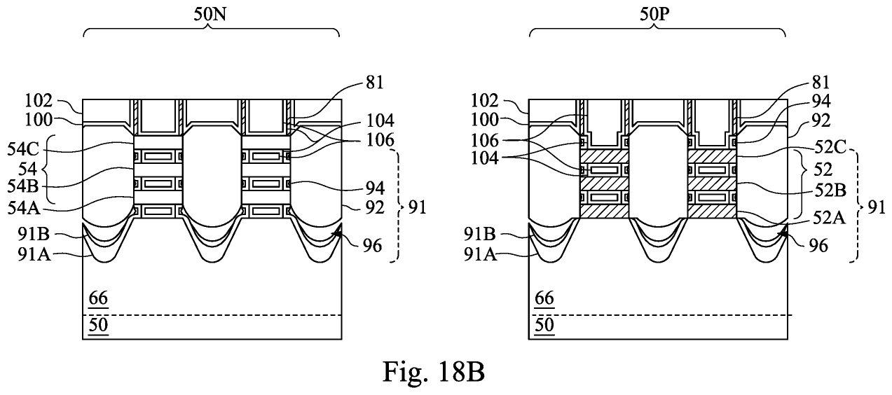

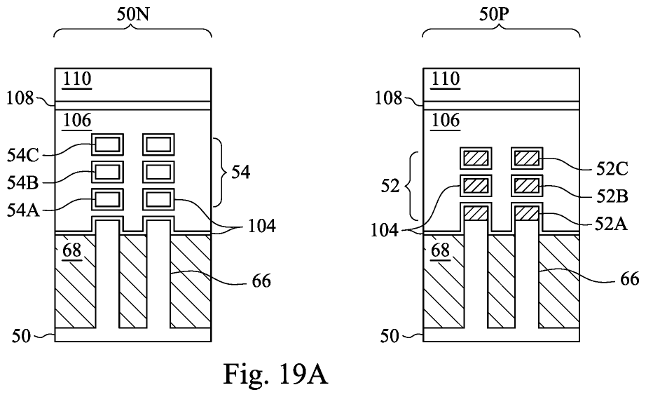

In FIGS. 18A and 18B, gate dielectric layers 104 and gate electrodes 106 are formed for replacement gates. The gate dielectric layers 104 are deposited conformally in the recesses 98. In the n-type region 50N, the gate dielectric layers 104 may be formed on top surfaces of the STI regions 68; top surfaces and side surfaces of the fins 66; top surfaces, side surfaces, and bottom surfaces of the second nanostructures 54; and side surfaces of the inner spacers 91 and the first spacers 81. In the p-type region 50P, the gate dielectric layers 104 may be formed on top surfaces of the STI regions 68; side surfaces of the fins 66; top surfaces, side surfaces, and bottom surfaces of the first nanostructures 52; and side surfaces of the inner spacers 91 and the first spacers 81. The gate dielectric layers 104 may be deposited on top surfaces of upper inner spacers 91, and may have a stepped structure. The gate dielectric layers 104 may be deposited on top surfaces of the first ILD 102, the CESL 100, and the first spacers 81.

In some embodiments, the gate dielectric layers 104 comprise one or more dielectric layers, such as an oxide, a metal oxide, the like, or combinations thereof. For example, the gate dielectric layers 104 may comprise a silicon oxide layer and a metal oxide layer over the silicon oxide layer. In some embodiments, the gate dielectric layers 104 include a high-k dielectric material, and in these embodiments, the gate dielectric layers 104 may have a k-value greater than about 7.0, and may include a metal oxide or a silicate of hafnium, aluminum, zirconium, lanthanum, manganese, barium, titanium, lead, and combinations thereof. The structure of the gate dielectric layers 104 may be the same or different in the n-type region 50N and the p-type region 50P. The formation methods of the gate dielectric layers 104 may include molecular-beam deposition (MBD), ALD, PECVD, and the like.

The gate electrodes 106 are deposited over the gate dielectric layers 104 and fill the remaining portions of the recesses 98. The gate electrodes 106 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 106 are illustrated in FIGS. 18A and 18B, the gate electrodes 106 may comprise any number of liner layers, any number of work function tuning layers, and a fill material. Any combination of the layers which make up the gate electrodes 106 may be deposited in the n-type region 50N between adjacent ones of the second nanostructures 54 and between the second nanostructure 54A and the fins 66, and may be deposited in the p-type region 50P between adjacent ones of the first nanostructures 52.

The formation of the gate dielectric layers 104 in the n-type region 50N and the p-type region 50P may occur simultaneously such that the gate dielectric layers 104 in each region are formed from the same materials, and the formation of the gate electrodes 106 may occur simultaneously such that the gate electrodes 106 in each region are formed from the same materials. In some embodiments, the gate dielectric layers 104 in each region may be formed by distinct processes, such that the gate dielectric layers 104 may be different materials and/or have a different number of layers, and/or the gate electrodes 106 in each region may be formed by distinct processes, such that the gate electrodes 106 may be different materials and/or have a different number of layers. Various masking steps may be used to mask and expose appropriate regions when using distinct processes.

After the filling of the recesses 98, a planarization process, such as a CMP, may be performed to remove the excess portions of the gate dielectric layers 104 and the material of the gate electrodes 106, which excess portions are over the top surfaces of the first ILD 102, the CESL 100, and the first spacers 81. The remaining portions of material of the gate electrodes 106 and the gate dielectric layers 104 thus form replacement gate structures of the resulting nanostructure FETs. The gate electrodes 106 and the gate dielectric layers 104 may be collectively referred to as “gate structures.”

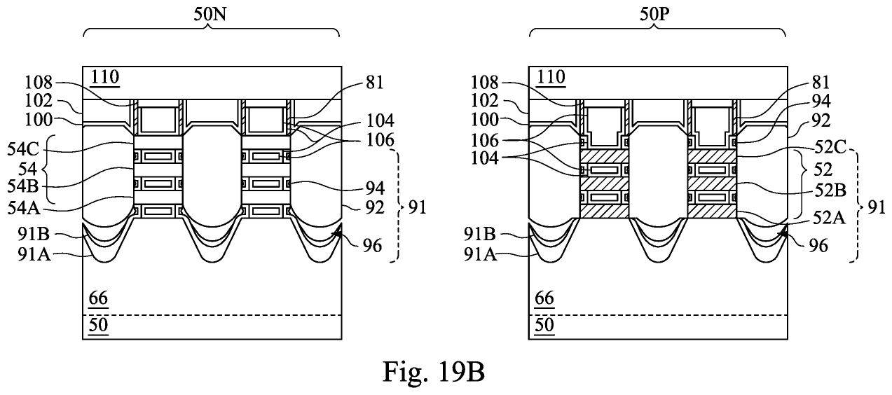

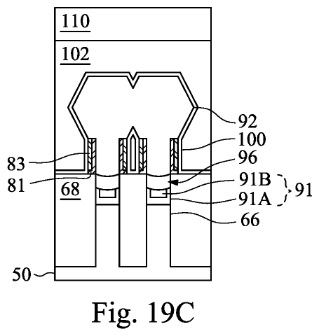

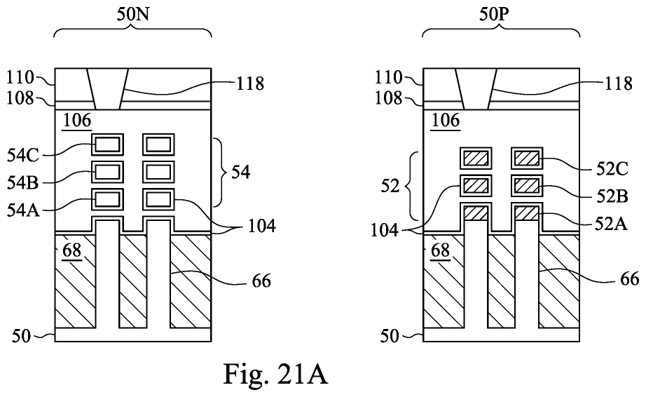

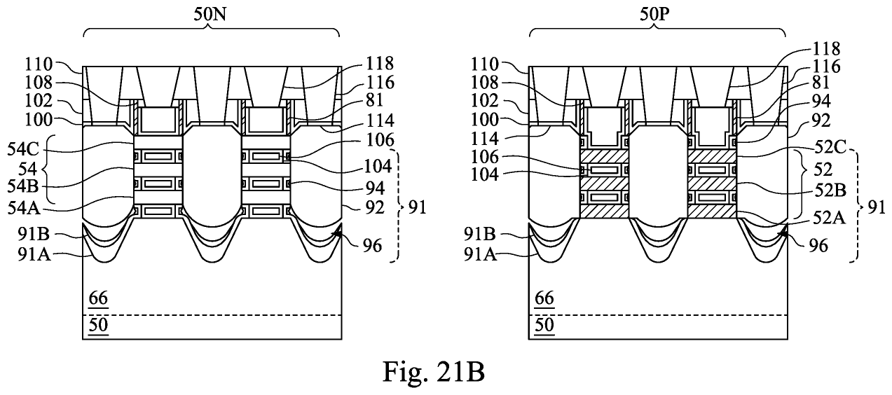

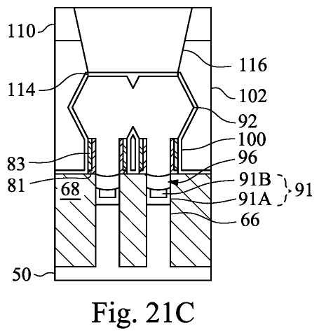

In FIGS. 19A through 19C, the gate structures (including the gate dielectric layers 104 and the corresponding overlying gate electrodes 106) are recessed, so that recesses are formed directly over each of the gate structures and between opposing portions of the first spacers 81. Gate caps 108 comprising one or more layers of dielectric material, such as silicon nitride, silicon oxynitride, or the like, are filled in the recesses, followed by a planarization process to remove excess portions of the dielectric material extending over the first ILD 102, the CESL 100, and the first spacers 81. Subsequently formed gate contacts (such as the gate contacts 118, discussed below with respect to FIGS. 21A and 21B) penetrate through the gate caps 108 to contact top surfaces of the recessed gate electrodes 106.

Further in FIGS. 19A through 19C, a second ILD 110 is deposited over the first ILD 102, the CESL 100, the first spacers 81, and the gate caps 108. In some embodiments, the second ILD 110 is a flowable film formed by FCVD. In some embodiments, the second ILD 110 is formed of a dielectric material such as PSG, BSG, BPSG, USG, or the like, and may be deposited by any suitable method, such as CVD, PECVD, or the like.

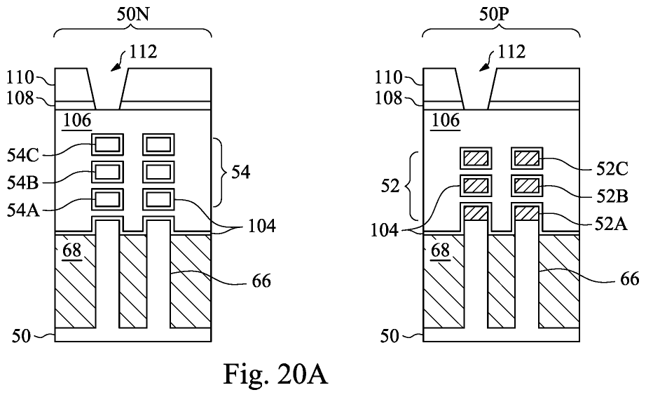

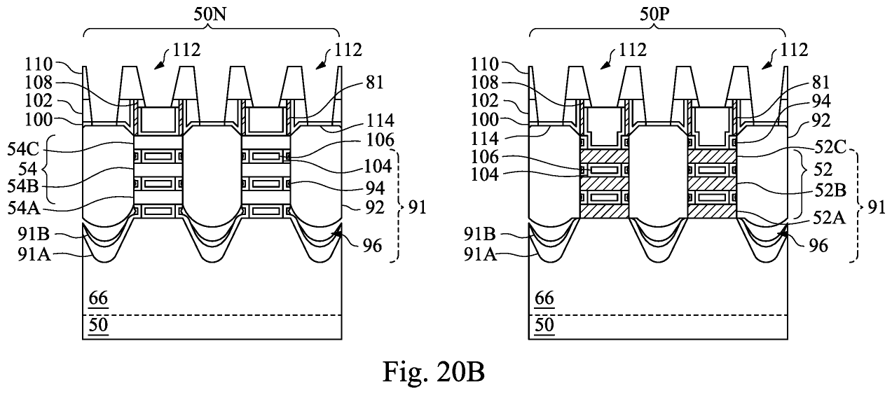

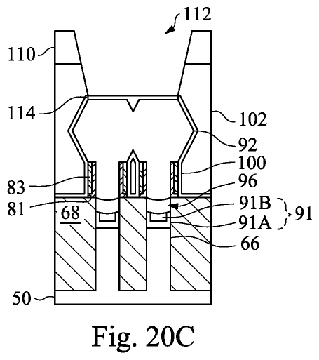

In FIGS. 20A through 20C, the second ILD 110, the first ILD 102, the CESL 100, and the gate caps 108 are etched to form recesses 112 exposing surfaces of the epitaxial source/drain regions 92 and/or the gate electrodes 106. The recesses 112 may be formed by etching using an anisotropic etching process, such as RIE, NBE, or the like. In some embodiments, the recesses 112 may be etched through the second ILD 110 and the first ILD 102 using a first etching process; may be etched through the gate caps 108 using a second etching process; and may be etched through the CESL 100 using a third etching process. A mask, such as a photoresist, may be formed and patterned over the second ILD 110 to mask portions of the second ILD 110 from the first etching process and the second etching process. In some embodiments, the etching process may over-etch, and therefore, the recesses 112 extend into the epitaxial source/drain regions 92 and/or the gate electrodes 106. Bottom surfaces of the recesses 112 may be level with (e.g., at a same level, or having a same distance from the substrate 50), or lower than (e.g., closer to the substrate 50) top surfaces of the epitaxial source/drain regions 92 and/or the gate electrodes 106. Although FIG. 20B illustrate the recesses 112 as exposing the epitaxial source/drain regions 92 and the gate electrodes 106 in a same cross section, in some embodiments, the epitaxial source/drain regions 92 and the gate electrodes 106 may be exposed in different cross-sections, thereby reducing the risk of shorting subsequently formed contacts.

After the recesses 112 are formed, silicide regions 114 are formed over the epitaxial source/drain regions 92. In some embodiments, the silicide regions 114 are formed by depositing a metal (not separately illustrated) capable of reacting with the semiconductor materials of the underlying epitaxial source/drain regions 92 (e.g., silicon, silicon germanium, germanium, or the like) to form silicide or germanide regions. The metal may include nickel, cobalt, titanium, tantalum, platinum, tungsten, other noble metals, other refractory metals, rare earth metals or their alloys. The metal is deposited over the exposed portions of the epitaxial source/drain regions 92, then a thermal anneal process is performed to form the silicide regions 114. The un-reacted portions of the deposited metal are removed, for example, by an etching process. Although the silicide regions 114 are referred to as silicide regions, the silicide regions 114 may also be germanide regions, or silicon germanide regions (e.g., regions comprising silicide and germanide). In some embodiments, the silicide regions 114 comprise titanium silicide (TiSi) having thicknesses in a range from about 2 nm to about 10 nm.

In FIGS. 21A through 21C, source/drain contacts 116 and gate contacts 118 (each of which may also be referred to as contact plugs) are formed in the recesses 112. The source/drain contacts 116 and the gate contacts 118 may each comprise one or more layers, such as barrier layers, diffusion layers, and fill materials. For example, in some embodiments, the source/drain contacts 116 and the gate contacts 118 each include a barrier layer and a conductive material. The source/drain contacts 116 and the gate contacts 118 are electrically coupled to the underlying conductive features (e.g., the gate electrodes 106 and the silicide regions 114 in the illustrated embodiment). The gate contacts 118 are electrically coupled to the gate electrodes 106. The source/drain contacts 116 are electrically coupled to the epitaxial source/drain regions 92 through the silicide regions 114. The barrier layer may include titanium, titanium nitride, tantalum, tantalum nitride, or the like. The conductive material may include copper, a copper alloy, silver, gold, tungsten, cobalt, aluminum, nickel, or the like. A planarization process, such as a CMP, may be performed to remove excess material of the source/drain contacts 116 and the gate contacts 118 from surfaces of the second ILD 110.

FIGS. 22A through 22C illustrate cross-sectional views of a device according to some alternative embodiments. In FIGS. 22A through 22C, like reference numerals indicate like elements formed by like processes to the structure of FIGS. 21A through 21C. In the embodiment of FIGS. 22A through 22C, channel regions in the n-type region 50N and the p-type region 50P comprise a same material. For example, the second nanostructures 54, which comprise silicon, provide channel regions for p-type nanostructure FETs in the p-type region 50P and for n-type nanostructure FETs in the n-type region 50N. The structure of FIGS. 22A through 22C may be formed, for example, by removing the first nanostructures 52 from both the p-type region 50P and the n-type region 50N simultaneously; depositing the gate dielectric layers 104 and the gate electrodes 106P (e.g., gate electrodes suitable for p-type nanostructure FETs) around the second nanostructures 54 in the p-type region 50P; and depositing the gate dielectric layers 104 and the gate electrodes 106N (e.g., gate electrodes suitable for n-type nanostructure FETs) around the second nanostructures 54 in the n-type region 50N. Materials of the epitaxial source/drain regions 92 may be different in the n-type region 50N and the p-type region 50P as explained above.

Embodiments may achieve advantages. For example, including the side air gaps 94 reduces an effective dielectric constant between the epitaxial source/drain regions 92 and the gate structures (including the gate dielectric layers 104 and the gate electrodes 106), reduces capacitance, and improves device performance. Including the inner spacers 91 and the bottom air gaps 96 between the epitaxial source/drain regions and the substrate 50 improves isolation of the epitaxial source/drain regions 92, reduces leakage, reduces capacitance, and improves device performance. Both the bottom air gaps 96 and the side air gaps 94 may contribute to improved AC performance.

In accordance with an embodiment, a semiconductor device includes a semiconductor substrate; a first channel region on the semiconductor substrate; a gate structure on the first channel region; a first source/drain region adjacent the gate structure and the first channel region; a first inner spacer layer between the first source/drain region and the semiconductor substrate in a first direction perpendicular to a major surface of the semiconductor substrate; and a first air gap between the first source/drain region and the first inner spacer layer in the first direction. In an embodiment, the semiconductor device further includes a second inner spacer layer between the gate structure and the first source/drain region in a second direction parallel to the major surface of the semiconductor substrate; and a second air gap between the first source/drain region and the second inner spacer layer in the second direction. In an embodiment, the first air gap includes air in physical contact with surfaces of the first inner spacer layer and the first source/drain region. In an embodiment, the semiconductor device further includes a second inner spacer layer between the first inner spacer layer and the first air gap in the first direction, the first inner spacer layer including a first material, and the second inner spacer layer including a second material different from the first material. In an embodiment, the first source/drain region is in physical contact with the semiconductor substrate. In an embodiment, the first inner spacer layer is in physical contact with the gate structure. In an embodiment, the first air gap is between the first source/drain region and the gate structure in a second direction parallel to the major surface of the semiconductor substrate.

In accordance with another embodiment, a semiconductor device includes a semiconductor substrate; a plurality of channel regions on the semiconductor substrate in a first direction perpendicular to a major surface of the semiconductor substrate; a gate structure on the plurality of channel regions; a source/drain region adjacent the gate structure; and a first spacer structure between the source/drain region and the semiconductor substrate, the first spacer structure including a first spacer layer, the first spacer layer including a first material; a second spacer layer on the first spacer layer, the second spacer layer including a second material different from the first material; and a bottom air gap between the second spacer layer and the source/drain region. In an embodiment, the semiconductor device further includes an inner spacer structure between the source/drain region and the gate structure, the inner spacer structure including a first inner spacer layer, the first inner spacer layer including the first material; a second inner spacer layer on the first inner spacer layer, the second inner spacer layer including the second material; and a side air gap between the second inner spacer layer and the source/drain region. In an embodiment, the first spacer layer and the first inner spacer layer include a continuous material. In an embodiment, the semiconductor device further includes an inner spacer structure between the source/drain region and the gate structure, the inner spacer structure including a first inner spacer layer, the first inner spacer layer including the first material; and a second inner spacer layer on the first inner spacer layer, the second inner spacer layer including the second material, side surfaces of the first inner spacer layer and the second inner spacer layer being aligned with side surfaces of the plurality of channel regions. In an embodiment, the source/drain region is in physical contact with the first spacer layer. In an embodiment, the source/drain region is in physical contact with the semiconductor substrate. In an embodiment, the bottom air gap is in physical contact with the semiconductor substrate.

In accordance with yet another embodiment, a method includes forming a gate structure on a first channel region; forming a first recess in a substrate adjacent the gate structure; depositing a first spacer layer in the first recess; depositing a second spacer layer on the first spacer layer in the first recess; etching the first spacer layer and the second spacer layer using a first etching process to form a first inner spacer portion and a second inner spacer portion, respectively, in the first recess; and forming a source/drain region in the first recess, a bottom air gap being enclosed by the source/drain region and the first inner spacer portion. In an embodiment, the first etching process etches the second spacer layer at a rate at least five times greater than a rate at which the first etching process etches the first spacer layer. In an embodiment, the first spacer layer includes a first material, and the second spacer layer includes a second material different from the first material. In an embodiment, the method further includes forming a multi-layer stack on the substrate, the multi-layer stack including alternating layers of a first semiconductor material and a second semiconductor material different from the first semiconductor material, the gate structure being formed on the multi-layer stack, the first recess being formed through the multi-layer stack and forms a plurality of nanostructures from the multi-layer stack; and etching a sidewall of the first semiconductor material to form a sidewall recess, the first spacer layer and the second spacer layer being deposited in the sidewall recess and filling the sidewall recess, etching the first spacer layer and the second spacer layer using the first etching process forming a third inner spacer portion and a fourth inner spacer portion, respectively, in the sidewall recess. In an embodiment, the first inner spacer portion and the third inner spacer portion are continuous. In an embodiment, forming the source/drain region forms a side air gap in the sidewall recess enclosed by the source/drain region and the third inner spacer portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a semiconductor substrate;
a first channel region on the semiconductor substrate;
a gate structure on the first channel region;
a first source/drain region adjacent the gate structure and the first channel region;
a first inner spacer layer between the first source/drain region and the semiconductor substrate in a first direction perpendicular to a major surface of the semiconductor substrate; and
a first air gap between the first source/drain region and the first inner spacer layer in the first direction.

2. The semiconductor device of claim 1, further comprising:
a second inner spacer layer between the gate structure and the first source/drain region in a second direction parallel to the major surface of the semiconductor substrate; and
a second air gap between the first source/drain region and the second inner spacer layer in the second direction.

3. The semiconductor device of claim 1, wherein the first air gap comprises air in physical contact with surfaces of the first inner spacer layer and the first source/drain region.

4. The semiconductor device of claim 1, further comprising a second inner spacer layer between the first inner spacer layer and the first air gap in the first direction, wherein the first inner spacer layer comprises a first material, and wherein the second inner spacer layer comprises a second material different from the first material.

5. The semiconductor device of claim 1, wherein the first source/drain region is in physical contact with the semiconductor substrate.

6. The semiconductor device of claim 1, wherein the first inner spacer layer is in physical contact with the gate structure.

7. The semiconductor device of claim 1, wherein the first air gap is between the first source/drain region and the gate structure in a second direction parallel to the major surface of the semiconductor substrate.

8. A semiconductor device comprising:
a semiconductor substrate;
a plurality of channel regions on the semiconductor substrate in a first direction perpendicular to a major surface of the semiconductor substrate;
a gate structure on the plurality of channel regions;
a source/drain region adjacent the gate structure; and
a first spacer structure between the source/drain region and the semiconductor substrate, the first spacer structure comprising:
a first spacer layer, the first spacer layer comprising a first material;
a second spacer layer on the first spacer layer, the second spacer layer comprising a second material different from the first material; and
a bottom air gap between the second spacer layer and the source/drain region.

9. The semiconductor device of claim 8, further comprising an inner spacer structure between the source/drain region and the gate structure, the inner spacer structure comprising:
a first inner spacer layer, the first inner spacer layer comprising the first material;
a second inner spacer layer on the first inner spacer layer, the second inner spacer layer comprising the second material; and
a side air gap between the second inner spacer layer and the source/drain region.

10. The semiconductor device of claim 9, wherein the first spacer layer and the first inner spacer layer comprise a continuous material.

11. The semiconductor device of claim 8, further comprising an inner spacer structure between the source/drain region and the gate structure, the inner spacer structure comprising:
a first inner spacer layer, the first inner spacer layer comprising the first material; and
a second inner spacer layer on the first inner spacer layer, the second inner spacer layer comprising the second material, wherein side surfaces of the first inner spacer layer and the second inner spacer layer are aligned with side surfaces of the plurality of channel regions.

12. The semiconductor device of claim 8, wherein the source/drain region is in physical contact with the first spacer layer.

13. The semiconductor device of claim 8, wherein the source/drain region is in physical contact with the semiconductor substrate.

14. The semiconductor device of claim 8, wherein the bottom air gap is in physical contact with the semiconductor substrate.

15. A method comprising:
forming a gate structure on a first channel region;
forming a first recess in a substrate adjacent the gate structure;
depositing a first spacer layer in the first recess;
depositing a second spacer layer on the first spacer layer in the first recess;
etching the first spacer layer and the second spacer layer using a first etching process to form a first inner spacer portion and a second inner spacer portion, respectively, in the first recess; and
forming a source/drain region in the first recess, wherein a bottom air gap is enclosed by the source/drain region and the first inner spacer portion.

16. The method of claim 15, wherein the first etching process etches the second spacer layer at a rate at least five times greater than a rate at which the first etching process etches the first spacer layer.

17. The method of claim 15, wherein the first spacer layer comprises a first material, and wherein the second spacer layer comprises a second material different from the first material.

18. The method of claim 15, further comprising:
forming a multi-layer stack on the substrate, the multi-layer stack comprising alternating layers of a first semiconductor material and a second semiconductor material different from the first semiconductor material, wherein the gate structure is formed on the multi-layer stack, wherein the first recess is formed through the multi-layer stack and forms a plurality of nanostructures from the multi-layer stack; and
etching a sidewall of the first semiconductor material to form a sidewall recess, wherein the first spacer layer and the second spacer layer are deposited in the sidewall recess and fill the sidewall recess, wherein etching the first spacer layer and the second spacer layer using the first etching process forms a third inner spacer portion and a fourth inner spacer portion, respectively, in the sidewall recess.

19. The method of claim 18, wherein the first inner spacer portion and the third inner spacer portion are continuous.

20. The method of claim 18, wherein forming the source/drain region forms a side air gap in the sidewall recess enclosed by the source/drain region and the third inner spacer portion.
